(19) United States
(12) Patent Application Publication
(10) Pub. No.: US 2025/0089292 A1
(43) Pub. Date: Mar. 13, 2025

(54) SILICON CARBIDE SEMICONDUCTOR DEVICE

(71) Applicant: SUMITOMO ELECTRIC INDUSTRIES, LTD., Osaka (JP)

(72) Inventor: Yu SAITOH, Osaka (JP)

(21) Appl. No.: 18/728,625

(22) PCT Filed: Feb. 27, 2023
(86) PCT No.: PCT/JP2023/007114

§ 371 Date: Jul. 12, 2024

(30) Foreign Application Priority Data
Mar. 4, 2022 (JP) 2022-033297

(51) Int. Cl. H01L 29/78; H01L 29/06; H01L 29/16

(52) U.S. Cl. CPC H10D 30/668; H10D 62/102; H10D 62/8325

(57) ABSTRACT

A silicon carbide semiconductor device includes an n-type drift region, a p-type body region, an n-type source region, a p-type contact region, a gate trench extending in a first direction, a gate insulating film, a gate electrode, a source electrode, an interlayer insulating film, a p-type electric field mitigation region, and a p-type connection region connecting the contact region and the electric field mitigation region. The electric field mitigation region includes a first region having a first dimension in a second direction perpendicular to the first direction, and a second region connected to the first region in the first direction and having a second dimension in the second direction smaller than the first dimension. The contact region includes a third region exposed via a contact hole provided in the interlayer insulating film and connected to the source electrode.

### TECHNICAL FIELD

The present disclosure relates to silicon carbide semiconductor devices.

This application is based upon and claims priority to Japanese Patent Application No. 2022-033297, filed on Mar. 4, 2022, the entire contents of which are incorporated herein by reference.

### BACKGROUND ART

A trench type MOSFET (Metal Oxide Semiconductor Field Effect Transistor), having an electric field shield region provided below a gate trench that is formed in a principal surface, is disclosed as an example of a silicon carbide semiconductor device (refer to Patent Documents 1 and 2, for example).

### PRIOR ART DOCUMENTS

### Patent Documents

Patent Document 1: Japanese Laid-Open Patent Publication No. 2014-41990
Patent Document 2: Japanese Laid-Open Patent Publication No. 2012-169385

### DISCLOSURE OF THE INVENTION

A silicon carbide semiconductor device according to the present disclosure includes: a silicon carbide substrate having a first principal surface and a second principal surface opposite to the first principal surface; a source electrode; a gate insulating film; a gate electrode provided on the gate insulating film so that the gate insulating film is interposed between the silicon carbide substrate and the gate electrode; and an interlayer insulating film covering the gate electrode, wherein: the silicon carbide substrate includes: a drift region having a first conductivity type; a body region provided on the drift region and having a second conductivity type different from the first conductivity type; a source region provided on the body region so as to be spaced apart from the drift region, and having the first conductivity type; and a contact region provided on the body region and having the second conductivity type, a gate trench is provided in the first principal surface, and is defined by a side surface penetrating the source region and the body region and reaching the drift region, and a bottom surface continuous with the side surface, the gate trench extending in a first direction parallel to the first principal surface, the source electrode is connected to the source region and the contact region, the gate insulating film makes contact with the side surface and the bottom surface, the silicon carbide substrate includes: an electric field mitigation region provided between the bottom surface and the second principal surface, extending in the first direction, and having the second conductivity type; and a connection region electrically connecting the contact region and the electric field mitigation region, and having the second conductivity type, the electric field mitigation region includes: a first region having a first dimension in a second direction perpendicular to the first direction; and a second region connected to the first region in the first direction and having a second dimension smaller than the first dimension in the second direction, a contact hole is formed in the interlayer insulating film, extends in the first direction, and exposes a portion of the source region, the contact region includes a third region exposed via the contact hole and connected to the source electrode, in a plan view viewed in a direction perpendicular to the first principal surface, the gate trench and the electric field mitigation region overlap a virtual straight line extending in the first direction, and the connection region makes contact with the electric field mitigation region on the virtual straight line, and the first region and the third region are arranged side by side in the second direction.

### BRIEF DESCRIPTION OF THE DRAWINGS

FIG. 1 is a perspective cross sectional view (part 1) illustrating a configuration of a silicon carbide semiconductor device according to an embodiment.

FIG. 2 is a perspective cross sectional view (part 2) illustrating the configuration of the silicon carbide semiconductor device according to the embodiment.

FIG. 3 is a diagram illustrating a configuration of an interlayer insulating film and a first principal surface of the silicon carbide semiconductor device according to the embodiment.

FIG. 4 is a diagram illustrating a configuration of an electric field mitigation region.

FIG. 5 is a cross sectional view (part 1) illustrating the configuration of the silicon carbide semiconductor device according to the embodiment.

FIG. 6 is a cross sectional view (part 2) illustrating the configuration of the silicon carbide semiconductor device according to the embodiment.

FIG. 7 is a cross sectional view (part 3) illustrating the configuration of the silicon carbide semiconductor device according to the embodiment.

FIG. 8 is a cross sectional view (part 4) illustrating the configuration of the silicon carbide semiconductor device according to the embodiment.

FIG. 9 is a cross sectional view (part 5) illustrating the configuration of the silicon carbide semiconductor device according to the embodiment.

FIG. 10 is a cross sectional view (part 1) illustrating a method for manufacturing the silicon carbide semiconductor device according to the embodiment.

FIG. 11 is a cross sectional view (part 2) illustrating the method for manufacturing the silicon carbide semiconductor device according to the embodiment.

FIG. 12 is a cross sectional view (part 3) illustrating the method for manufacturing the silicon carbide semiconductor device according to the embodiment.

FIG. 13 is a cross sectional view (part 4) illustrating the method for manufacturing the silicon carbide semiconductor device according to the embodiment.

FIG. 14 is a cross sectional view (part 5) illustrating the method for manufacturing the silicon carbide semiconductor device according to the embodiment.

FIG. 15 is a cross sectional view (part 6) illustrating the method for manufacturing the silicon carbide semiconductor device according to the embodiment.

FIG. 16 is a cross sectional view (part 7) illustrating the method for manufacturing the silicon carbide semiconductor device according to the embodiment.

FIG. 17 is a cross sectional view (part 8) illustrating the method for manufacturing the silicon carbide semiconductor device according to the embodiment.

FIG. 18 is a cross sectional view (part 9) illustrating the method for manufacturing the silicon carbide semiconductor device according to the embodiment.

FIG. 19 is a cross sectional view (part 10) illustrating the method for manufacturing the silicon carbide semiconductor device according to the embodiment.

FIG. 20 is a cross sectional view (part 11) illustrating the method for manufacturing the silicon carbide semiconductor device according to the embodiment.

FIG. 21 is a cross sectional view (part 12) illustrating the method for manufacturing the silicon carbide semiconductor device according to the embodiment.

FIG. 22 is a cross sectional view (part 13) illustrating the method for manufacturing the silicon carbide semiconductor device according to the embodiment.

FIG. 23 is a cross sectional view (part 14) illustrating the method for manufacturing the silicon carbide semiconductor device according to the embodiment.

FIG. 24 is a cross sectional view (part 15) depicting the method for manufacturing the silicon carbide semiconductor device according to the embodiment.

FIG. 25 is a cross sectional view (part 16) illustrating the method for manufacturing the silicon carbide semiconductor device according to the embodiment.

FIG. 26 is a cross sectional view (part 17) illustrating the method for manufacturing the silicon carbide semiconductor device according to the embodiment.

FIG. 27 is a cross sectional view (part 18) depicting the method for manufacturing the silicon carbide semiconductor device according to the embodiment.

FIG. 28 is a cross sectional view (part 19) illustrating the method for manufacturing the silicon carbide semiconductor device according to the embodiment.

FIG. 29 is a cross sectional view (part 20) depicting the method for manufacturing the silicon carbide semiconductor device according to the embodiment.

FIG. 30 is a cross sectional view illustrating a configuration of the silicon carbide semiconductor device according to a first modification of the embodiment.

FIG. 31 is a diagram illustrating a configuration of the interlayer insulating film and the first principal surface of the silicon carbide semiconductor device according to a second modification of the embodiment.

FIG. 32 is a cross sectional view illustrating a configuration of the silicon carbide semiconductor device according to the second modification of the embodiment.

FIG. 33 is a diagram illustrating a configuration of the interlayer insulating film and the first principal surface of the silicon carbide semiconductor device according to a third modification of the embodiment.

FIG. 34 is a cross sectional view illustrating a configuration of the silicon carbide semiconductor device according to the third modification of the embodiment.

FIG. 35 is a diagram illustrating a configuration of the interlayer insulating film and the first principal surface of the silicon carbide semiconductor device according to a fourth modification of the embodiment.

FIG. 36 is a cross sectional view illustrating a configuration of the silicon carbide semiconductor device according to the fourth modification of the embodiment.

### MODE OF CARRYING OUT THE INVENTION

### Problem to be Solved by the Present Disclosure

In recent years, a further reduction of drain leakage is desired with respect to silicon carbide semiconductor devices.

One object of the present disclosure is to provide a silicon carbide semiconductor device capable of reducing drain leakage.

### Effects of the Present Disclosure

According to the present disclosure, the drain leakage can be reduced.

Embodiments of the present disclosure will be described in the following.

### Description of Embodiments of the Present Disclosure

First, embodiments of the present disclosure will be described with examples. In the following description, the same or corresponding elements are designated by the same reference numerals, and the same description thereof will not be repeated. In the crystallographic description used in the present specification, an individual orientation is represented by [ ], a group orientation is represented by < >, an individual plane is represented by ( ) and a group plane is represented by { }. In addition, a negative crystallographic index is generally represented by “-” (bar) above the numeral, but in the present specification, a negative sign is added before the numeral. Further, in the present specification, an X1-X2 direction, a Y1-Y2 direction, and a Z1-Z2 direction are mutually perpendicular directions. A plane including the X1-X2 direction and the Y1-Y2 direction is referred to as an XY-plane, a plane including the Y1-Y2 direction and the Z1-Z2 direction is referred to as a YZ-plane, and a plane including the Z1-Z2 direction and the X1-X2 direction is referred to as a ZX-plane. For the sake of convenience, the Z1-Z2 direction is defined as a vertical direction, a Z1-side is defined as an upper side, and a Z2-side is defined as a lower side. Moreover, a plan view refers to a view of an object from the Z1-side, and a planar shape refers to a shape of the object in the plan view viewed from the Z1-side.
[1] A silicon carbide semiconductor device according to one aspect of the present disclosure includes: a silicon carbide substrate having a first principal surface and a second principal surface opposite to the first principal surface; a source electrode; a gate insulating film; a gate electrode provided on the gate insulating film so that the gate insulating film is interposed between the silicon carbide substrate and the gate electrode; and an interlayer insulating film covering the gate electrode, wherein: the silicon carbide substrate includes: a drift region having a first conductivity type; a body region provided on the drift region and having a second conductivity type different from the first conductivity type; a source region provided on the body region so as to be spaced apart from the drift region, and having the first conductivity type; and a contact region provided on the body region and having the second conductivity type, a gate trench is provided in the first principal surface, and is defined by a side surface penetrating the source region and the body region and reaching the drift region, and a bottom surface continuous with the side surface, the gate trench extending in a first direction parallel to the first principal surface, the source electrode is connected to the source region and the contact region, the gate insulating film makes contact with the side surface and the bottom surface, the silicon carbide substrate includes: an electric field mitigation region provided between the bottom surface and the second principal surface, extending in the first direction, and having the second conductivity type; and a connection region electrically connecting the contact region and the electric field mitigation region, and having the second conductivity type, the electric field mitigation region includes: a first region having a first dimension in a second direction perpendicular to the first direction; and a second region connected to the first region in the first direction and having a second dimension smaller than the first dimension in the second direction, a contact hole is formed in the interlayer insulating film, extends in the first direction, and exposes a portion of the source region, the contact region includes a third region exposed via the contact hole and connected to the source electrode, in a plan view viewed in a direction perpendicular to the first principal surface, the gate trench and the electric field mitigation region overlap a virtual straight line extending in the first direction, and the connection region makes contact with the electric field mitigation region on the virtual straight line, and the first region and the third region are arranged side by side in the second direction.

The contact region and the electric field mitigation region are electrically connected via the connection region. The contact region is electrically connected to the source electrode. Accordingly, the electric field mitigation region is electrically connected to the source electrode. For this reason, a feedback capacitance can be reduced, carriers can be supplied efficiently from the source electrode to the electric field mitigation region, and a switching loss can be reduced by accelerating a behavior of a depletion layer extending from the electric field mitigation region toward the drift region during a switching operation. In addition, the gate trench and the electric field mitigation region overlap the virtual straight line, and the connection region makes contact with the electric field mitigation region on the virtual straight line. Hence, the connection region is less likely to inhibit a current flowing along a portion of the side surface of the gate trench parallel to the first direction. Therefore, a sufficient current can be secured in an on state.

Further, the second dimension of the second region is smaller than the first dimension of the first region, and the first region and the third region are arranged side by side in the second direction in the plan view viewed in the direction perpendicular to the first principal surface. For this reason, concentration of an electric field at a position near the second principal surface of the contact region in an off state can be mitigated near the first region, while securing a region in which a drain current flows near the second region in the on state. Accordingly, a drain leakage caused by the concentration of the electric field can be reduced.
[2] In the silicon carbide semiconductor device according to [1], in the plan view viewed in the direction perpendicular to the first principal surface, a portion of the first region and a portion of the third region may overlap each other. In this case, the concentration of the electric field at a position near the second principal surface of the contact region can easily be mitigated, and the drain leakage can easily be reduced.
[3] In the silicon carbide semiconductor device according to [2], in the plan view viewed in the direction perpendicular to the first principal surface, the third region may have a first side extending in the first direction, and an entirety of the first side may overlap a portion of the first region. In this case, the concentration of the electric field at a position near the second principal surface of the contact region can more easily be mitigated, and the drain leakage can more easily be reduced.
[4] In the silicon carbide semiconductor device according to any one of [1] to [3], a plurality of the gate trenches may be provided at constant intervals so as to overlap the virtual straight line, and the connection region may be provided between adjacent gate trenches that are adjacent to each other in the first direction in the plan view viewed in the direction perpendicular to the first principal surface. When the connection region is provided between the adjacent gate trenches that are adjacent to each other in the first direction in the plan view viewed in the direction perpendicular to the first principal surface, it is easy to secure a large connection region, and to reduce an electrical resistance in the connection region.
[5] In the silicon carbide semiconductor device according to [4], in the plan view viewed in the direction perpendicular to the first principal surface, the contact region may further include a fourth region provided between the adjacent gate trenches that are adjacent to each other in the first direction, the third region may have a third dimension in the first direction, and the fourth region may have a fourth dimension in the first direction smaller than the third dimension. When the third dimension is larger than the fourth dimension, a wide range in which the current flows in the on state can be secured, while reducing a contact resistance between the third region and the source electrode.
[6] In the silicon carbide semiconductor device according to any one of [1] to [5], the third dimension may be more than one times and six or less times the fourth dimension. When the third dimension is more than one times and six of less times the fourth dimension, a wide range in which the current flows in the on state can be secured, while reducing a contact resistance between the third region and the source electrode, and further, a contact resistance between the source region and the source electrode can be reduced.
[7] In the silicon carbide semiconductor device according to [5] or [6], the source region and the third region may be alternately provided in the first direction, and the third dimension may be larger than a fifth dimension of the source region in the first direction. When the third dimension is larger than the fifth dimension, it is possible to reduce each of a contact resistance between the third region and the source electrode and a contact resistance between the source region and the source electrode.
[8] In the silicon carbide semiconductor device according to [5] or [6], the source region and the third region may be alternately provided in the first direction, and the third dimension may be 0.2 times or more and 0.6 times or less a sum of the third dimension and a fifth dimension of the source region in the first direction. When the third dimension is 0.2 times or more and 0.6 times or less the sum of the third dimension and the fifth dimension, it is possible to reduce each of a contact resistance between the third region and the source electrode and a contact resistance between the source region and the source electrode.
[9] In the silicon carbide semiconductor device according to any one of [5] to [8], the fourth region may be exposed from the interlayer insulating film, and the source electrode may also be connected to the fourth region. When the source electrode is also connected to the fourth region, it is possible to further reduce a contact resistance between the contact region and the source electrode.
[10] In the silicon carbide semiconductor device according to any one of [1] to [9], the contact region may include the third region on both sides of the gate trench in the second direction. When the contact region includes the third region on both sides of the gate trench in the second direction, an electrical resistance between the source electrode and the electric field mitigation region can easily be reduced.
[11] In the silicon carbide semiconductor device according to any one of [1] to [9], the contact region may include the third region only on one side of the gate trench in the second direction. When the contact region includes the third region only on one side of the gate trench in the second direction, the contact hole on the side not provided with the first region may be narrower than the contact hole on the side provided with the third region, and a cell pitch in the second direction can easily be reduced.
[12] In the silicon carbide semiconductor device according to any one of [1] to [11], a first effective concentration of an impurity of the second conductivity type in the contact region may be higher than a second effective concentration of an impurity of the second conductivity type in the connection region. When the first effective concentration is higher than the second effective concentration, a leakage current can easily be reduced while reducing a contact resistance between the contact region and the source electrode.
[13] In the silicon carbide semiconductor device according to any one of [1] to [12], the side surface of the gate trench may include a {0-33-8} plane. When the side surface includes the {0-33-8} plane, a satisfactory mobility can be obtained at the side surface of the gate trench, and a channel resistance can be reduced.

### EMBODIMENTS OF PRESENT DISCLOSURE

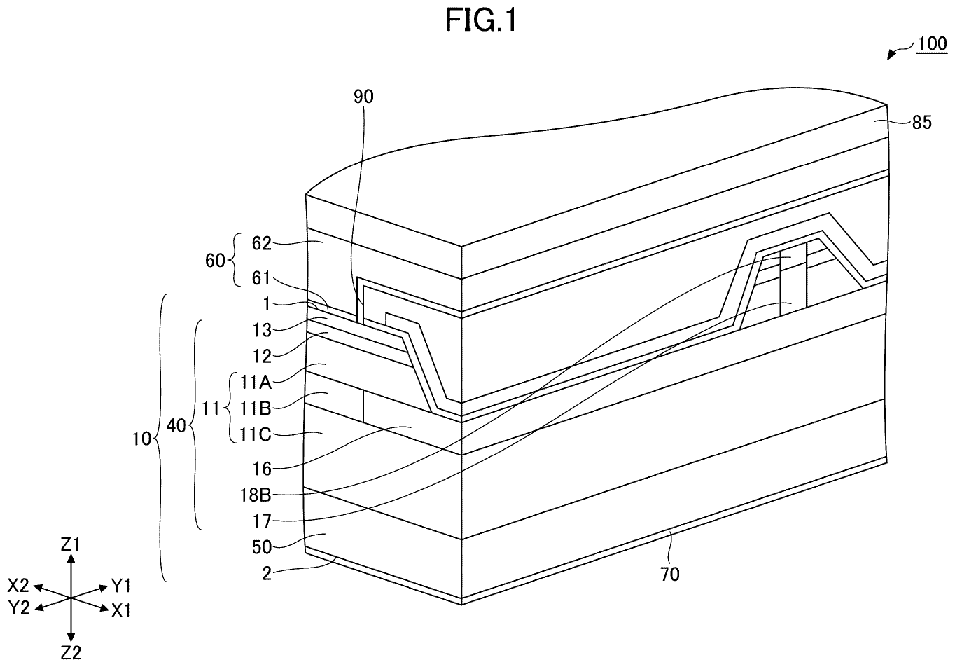

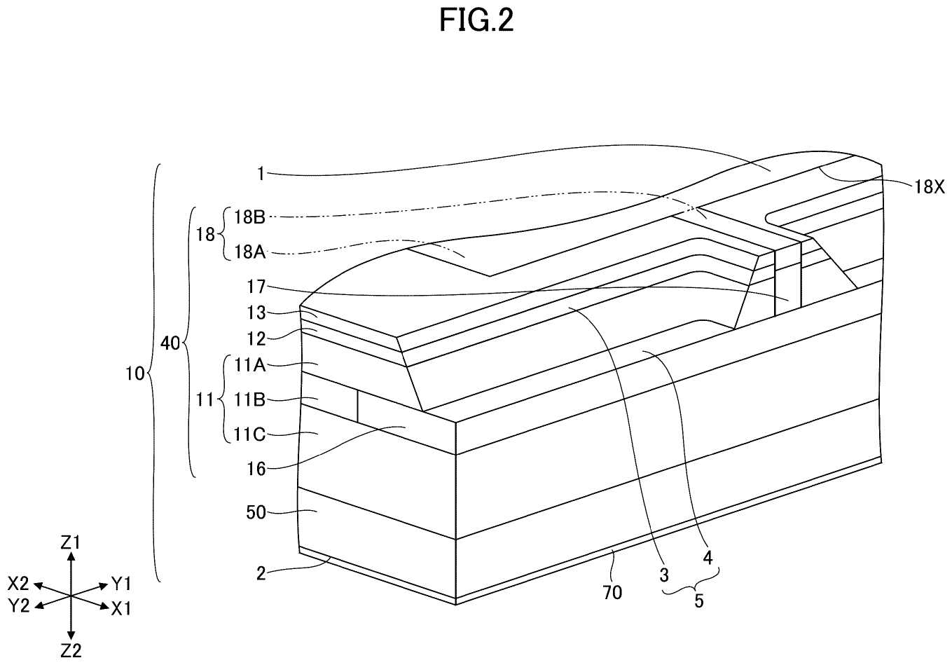

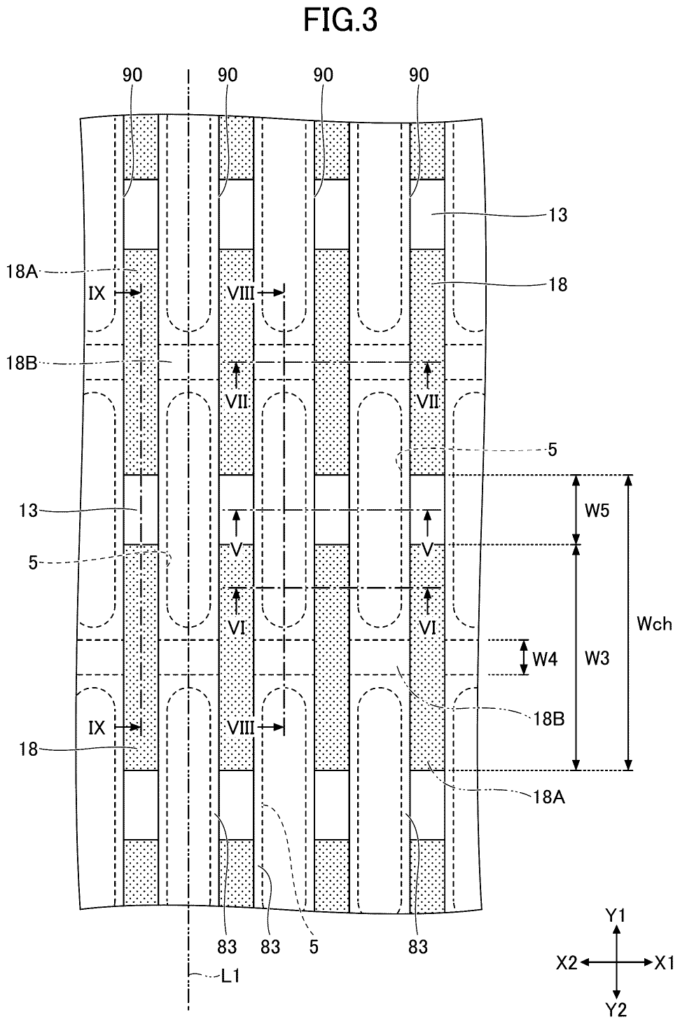

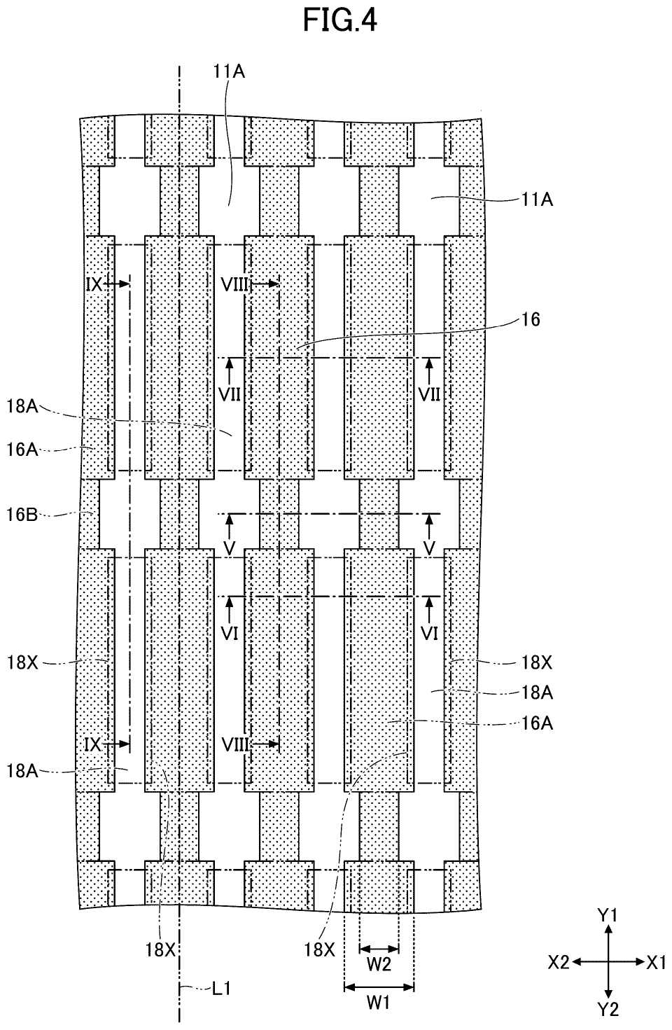

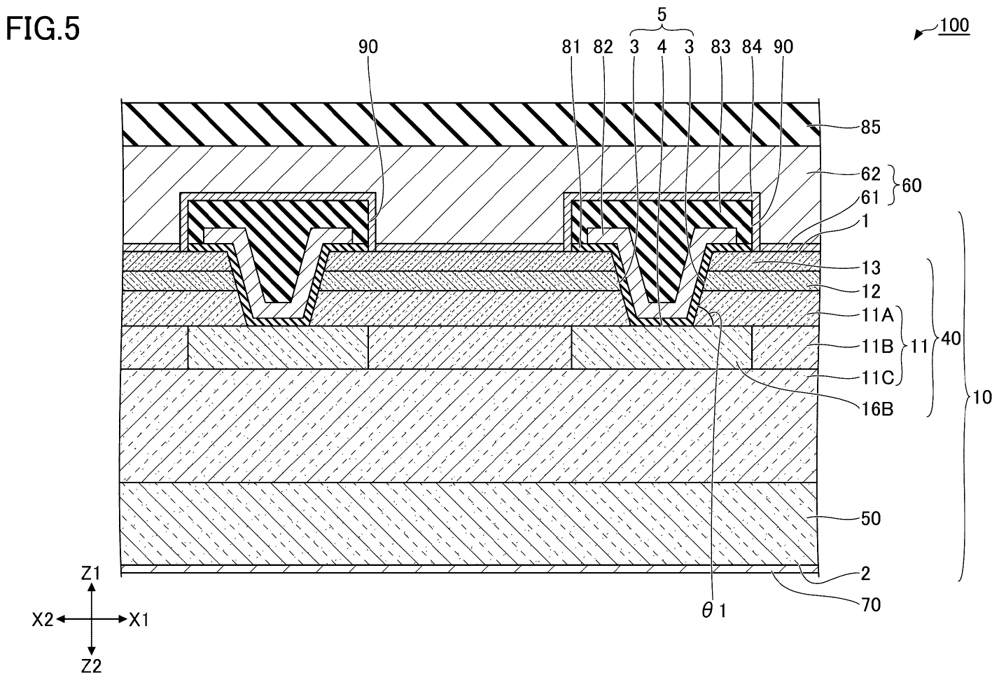

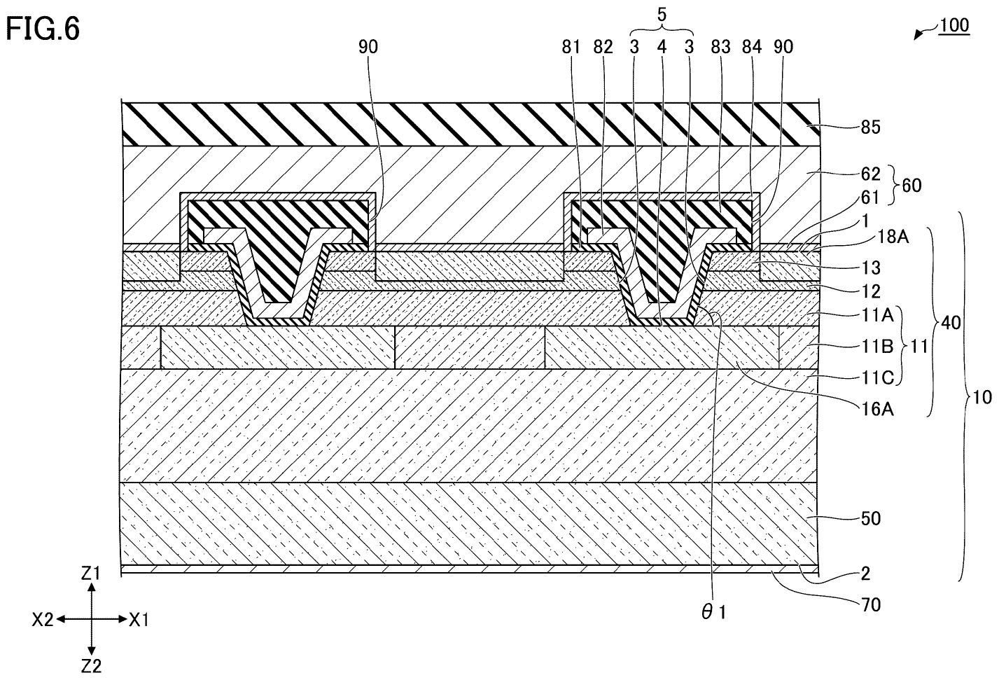

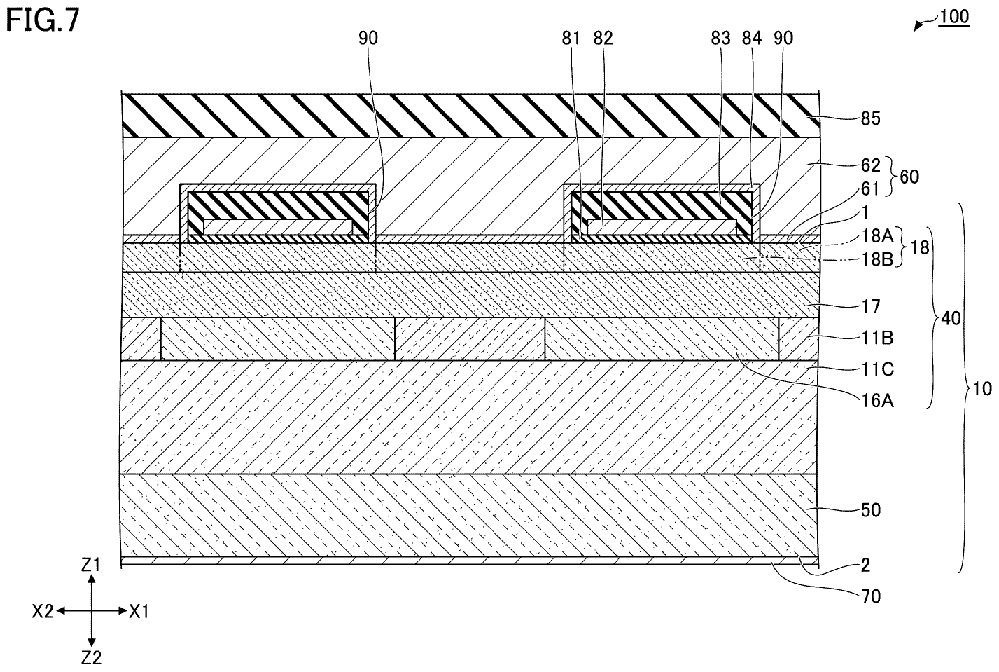

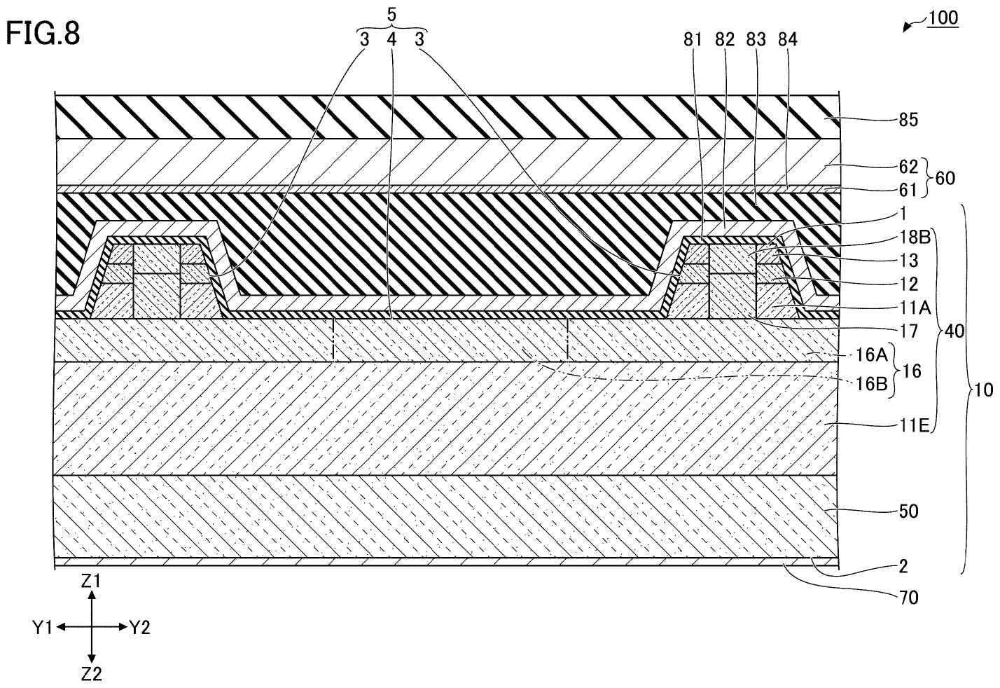

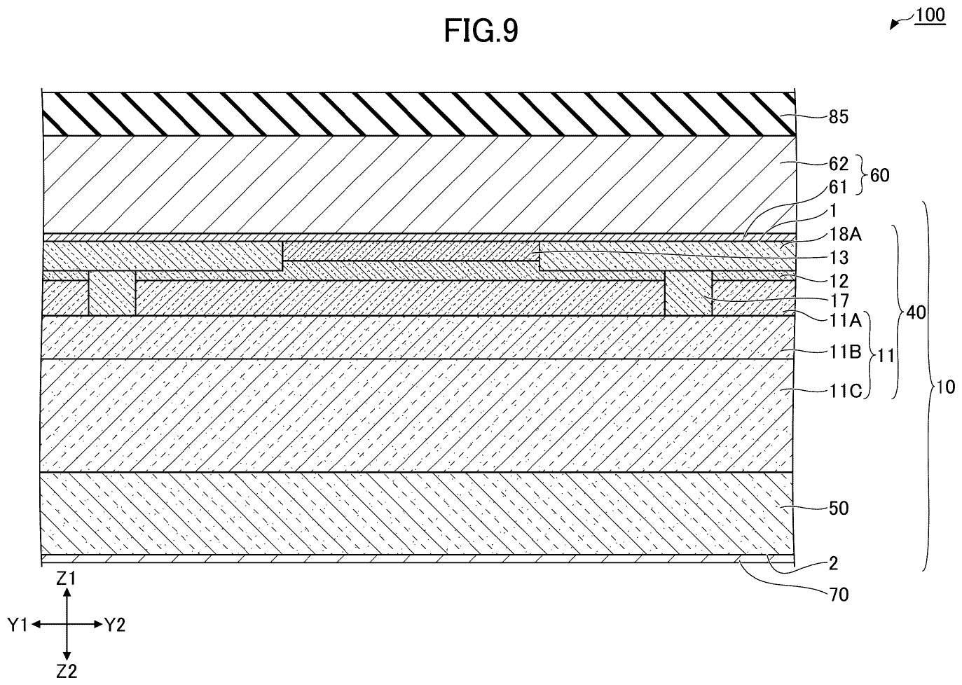

An embodiment of the present disclosure relates to a so-called vertical MOSFET (silicon carbide semiconductor device). FIG. 1 and FIG. 2 are perspective cross sectional views illustrating a configuration of a silicon carbide semiconductor device according to the embodiment. FIG. 2 illustrates a portion of an internal structure of the silicon carbide semiconductor device in perspective. FIG. 3 is a diagram illustrating a configuration of an interlayer insulating film and a first principal surface of the silicon carbide semiconductor device according to the embodiment. FIG. 4 is a diagram illustrating a configuration of an electric field mitigation region. FIG. 5 through FIG. 9 are cross sectional views illustrating the configuration of the silicon carbide semiconductor device according to the embodiment. FIG. 5 corresponds to a cross sectional view taken along a line V-V in FIG. 3 and FIG. 4. FIG. 6 corresponds to a cross sectional view taken along a line VI-VI in FIG. 3 and FIG. 4. FIG. 7 corresponds to a cross sectional view taken along a line VII-VII in FIG. 3 and FIG. 4. FIG. 8 corresponds to a cross sectional view taken along a line VIII-VIII in FIG. 3 and FIG. 4. FIG. 9 corresponds to a cross sectional view taken along a line IX-IX in FIG. 3 and FIG. 4.

As illustrated in FIG. 1 through FIG. 9, a MOSFET 100 according to the present embodiment mainly includes a silicon carbide substrate 10, a gate insulating film 81, a gate electrode 82, an interlayer insulating film 83, a source electrode 60, a drain electrode 70, a barrier metal film 84, and a passivation film 85. The silicon carbide substrate 10 includes a silicon carbide single crystal substrate 50, and a silicon carbide epitaxial layer 40 provided on the silicon carbide single crystal substrate 50. The silicon carbide substrate 10 has a first principal surface 1, and a second principal surface 2 opposite to the first principal surface 1. The silicon carbide epitaxial layer 40 forms the first principal surface 1, and the silicon carbide single crystal substrate 50 forms the second principal surface 2. The silicon carbide single crystal substrate 50 and the silicon carbide epitaxial layer 40 are formed of 4H polytype hexagonal silicon carbide, for example. The silicon carbide single crystal substrate 50 includes an n-type impurity, such as nitrogen (N) or the like, for example, and has an n-type conductivity (first conductivity type).

The first principal surface 1 is a {0001} plane or a plane inclined by an off angle of 8° or less in an off direction from the {0001} plane. Preferably, first principal surface 1 is a (000-1) plane or a plane inclined by an off angle of 8° or less in the off direction from the (000-1) plane. The off direction may be a <11-20> direction or a <1-100> direction, for example. The off angle may be 1° or more, or 2° or more, for example. The off angle may be 6° or less, or 4° or less.

The silicon carbide epitaxial layer 40 mainly includes a drift region 11, a body region 12, a source region 13, an electric field mitigation region 16, a connection region 17, and a contact region 18.

The drift region 11 includes an n-type impurity, such as nitrogen, phosphorus (P), or the like, for example, and has the n-type conductivity. The drift region 11 mainly includes a fifth region 11A, a sixth region 11B, and a seventh region 11C, for example.

The body region 12 is provided on the drift region 11. The body region 12 includes a p-type impurity, such as aluminum (Al) or the like, for example, and has a p-type conductivity (second conductivity type). An effective concentration of the p-type impurity in body region 12 is 5×10¹⁷ cm⁻³ or higher. A short channel effect (punch through) may occur when a depletion layer spreads from a pn junction region into a channel region and the entire channel region becomes the depletion layer. By increasing the effective concentration of the p-type impurity in body region 12, the spreading of the depletion layer formed in the channel region can be reduced. A thickness of the body region 12 may be less than 0.7 μm, for example. The effective concentration of the p-type impurity in the body region 12 is approximately 1×10¹⁸ cm⁻³, for example.

The source region 13 is provided on the body region 12, so as to be spaced apart from the drift region 11 by the body region 12. The source region 13 includes an n-type impurity, such as nitrogen, phosphorus, or the like, and has the n-type conductivity. The source region 13 forms the first principal surface 1. An effective concentration of the n-type impurity in the source region 13 may be higher than the effective concentration of the p-type impurity in the body region 12. The effective concentration of the n-type impurity in the source region 13 is approximately 1×10¹⁹ cm⁻³, for example.

The contact region 18 includes a p-type impurity, such as aluminum or the like, for example, and has the p-type conductivity. The contact region 18 forms the first principal surface 1. The contact region 18 mainly includes a third region 18A and a fourth region 18B, for example. An effective concentration of the p-type impurity in the contact region 18 is higher than the effective concentration of the p-type impurity in the body region 12 and higher than the effective concentration of the p-type impurity in the connection region 17, for example. The contact region 18 penetrates the source region 13, and makes contact with the body region 12. The effective concentration of the p-type impurity in the contact region 18 is 1×10¹⁸ cm⁻³ or higher and 1×10²⁰ cm⁻³ or lower, for example.

A gate trench 5, defined by a side surface 3 and a bottom surface 4, is provided in the first principal surface 1. The side surface 3 penetrates the source region 13, the body region 12, and the drift region 11, and reaches the electric field mitigation region 16. The bottom surface 4 is continuous with the side surface 3. The bottom surface 4 is located at the electric field mitigation region 16. The bottom surface 4 is a plane parallel to the second principal surface 2, for example. An angle 61 of the side surface 3 with respect to a plane including the bottom surface 4 is 45° or more and 65° or less, for example. The angle θ1 may be 50° or more, for example. The angle θ1 may be 60° or less, for example. The side surface 3 preferably has a {0-33-8} plane. The {0-33-8} plane is a crystal plane that provides excellent mobility.

As illustrated particularly in FIG. 3, when viewed in a plan view in a direction perpendicular to the first principal surface 1, the gate trench 5 overlaps a virtual straight line L1 extending in the Y1-Y2 direction (first direction) parallel to the first principal surface 1. When viewed in the plan view in the direction perpendicular to the first principal surface 1, the gate trench 5 is located on the virtual straight line L1. A plurality of gate trenches 5 are provided at constant intervals on the virtual straight line L1. In addition, in the plan view viewed in the direction perpendicular to the first principal surface 1, the plurality of gate trenches 5 are also provided at constant intervals in the X1-X2 direction (second direction) perpendicular to the Y1-Y2 direction. The plurality of gate trenches 5 may be provided in an array, for example.

The electric field mitigation region 16 includes a p-type impurity, such as Al or the like, and has the p-type conductivity. The electric field mitigation region 16 is located between the bottom surface 4 of the gate trench 5 and the second principal surface 2. An upper end surface of the electric field mitigation region 16 includes the bottom surface 4 of the gate trench 5, for example. A portion of the upper end surface of the electric field mitigation region 16 opposes a portion of a lower end surface of the body region 12. The electric field mitigation region 16 overlaps the virtual straight line L1 in the plan view viewed in the direction perpendicular to the first principal surface 1, similar to the gate trench 5. In the plan view viewed in the direction perpendicular to the first principal surface 1, the electric field mitigation region 16 is located on the virtual straight line L1. On the virtual straight line L1, the electric field mitigation region 16 may be provided in common to a plurality of gate trenches 5. In addition, in the plan view viewed in the direction perpendicular to the first principal surface 1, a plurality of electric field mitigation regions 16 are provided at constant intervals in the X1-X2 direction. The plurality of electric field mitigation regions 16 may be provided in a stripe shape. An effective concentration of the p-type impurity in the electric field mitigation region 16 is 5× 10¹⁷ cm⁻³ or higher and 5×10¹⁸ cm⁻³ or lower, for example.

The fifth region 11A of the drift region 11 is interposed between the body region 12 and the electric field mitigation region 16. The fifth region 11A makes contact with each of the body region 12 and the electric field mitigation region 16. The fifth region 11A is located closer to the second principal surface 2 than the body region 12 is to the second principal surface 2. The fifth region 11A is located closer to the first principal surface 1 than the electric field mitigation region 16 is to the first principal surface 1. An effective concentration of the n-type impurity in the fifth region 11A is 5×10¹⁵ cm⁻³ or higher and 5×10¹⁶ cm⁻³ or lower, for example.

The sixth region 11B is located closer to the second principal surface 2 than the fifth region 11A is to the second principal surface 2. The sixth region 11B is continuous with the fifth region 11A. The sixth region 11B makes contact with the electric field mitigation region 16 in the direction parallel to the second principal surface 2. The sixth region 11B and the electric field mitigation region 16 may be located on the same plane parallel to the second principal surface 2. An effective concentration of the n-type impurity in the sixth region 11B may be higher than the effective concentration of the n-type impurity in the fifth region 11A. The effective concentration of the n-type impurity in the sixth region 11B is 5×10¹⁶ cm⁻³ or higher and 5×10¹⁷ cm⁻³ or lower, for example.

The seventh region 11C is located closer to the second principal surface 2 than the sixth region 11B is to the second principal surface 2. The seventh region 11C is continuous with the sixth region 11B. The seventh region 11C makes contact with the electric field mitigation region 16. The seventh region 11C is located closer to the second principal surface 2 than the electric field mitigation region 16 is to the second principal surface 2. The seventh region 11C may be interposed between the sixth region 11B and the silicon carbide single crystal substrate 50. The seventh region 11C may be continuous with the silicon carbide single crystal substrate 50. An effective concentration of the n-type impurity in the seventh region 11C may be lower than the effective concentration of the n-type impurity in the sixth region 11B. The effective concentration of the n-type impurity in the seventh region 11C is 5×10¹⁵ cm⁻³ or lower and 5×10¹⁶ cm⁻³ or lower, for example.

The gate insulating film 81 is an oxide film, for example. The gate insulating film 81 is formed of a material including silicon dioxide, for example. The gate insulating film 81 makes contact with the side surface 3 and the bottom surface 4. The gate insulating film 81 makes contact with the electric field mitigation region 16 at the bottom surface 4. The gate insulating film 81 makes contact with each of the source region 13, the body region 12, and the drift region 11 at the side surface 3. The gate insulating film 81 may make contact with the source region 13 at the first principal surface 1.

The gate electrode 82 is provided on the gate insulating film 81. The gate electrode 82 is formed of polysilicon (poly-Si) including a conductive impurity, for example. The gate electrode 82 is disposed inside the gate trench 5. A portion of gate electrode 82 may be disposed on the first principal surface 1.

The interlayer insulating film 83 is provided in contact with the gate electrode 82 and the gate insulating film 81. The interlayer insulating film 83 is formed of a material including silicon dioxide, for example. The interlayer insulating film 83 electrically insulates the gate electrode 82 and the source electrode 60 from each other. A portion of the interlayer insulating film 83 may be provided inside the gate trench 5.

The interlayer insulating film 83 overlaps the virtual straight line L1 in the plan view viewed in the direction perpendicular to the first principal surface 1, similar to the gate trench 5 and the electric field mitigation region 16. On the virtual straight line L1, the interlayer insulating film 83 may be provided in common to the plurality of gate trenches 5. In the plan view viewed in the direction perpendicular to the first principal surface 1, contact holes 90 are formed in the interlayer insulating film 83 and the gate insulating film 81 at constant intervals in the X1-X2 direction. The contact holes 90 are provided such that gate trench 5 is located between adjacent contact holes 90 that are adjacent to each other in the X1-X2 direction when viewed in the plan view viewed in the direction perpendicular to the first principal surface 1. The contact hole 90 extends in the Y1-Y2 direction. The source region 13 and the contact region 18 are exposed from the interlayer insulating film 83 and the gate insulating film 81 via the contact hole 90. A dimension of the contact hole 90 in the X1-X2 direction may be 1 μm or less, for example.

As illustrated particularly in FIG. 3, the third region 18A of the contact region 18 is exposed from the interlayer insulating film 83 via the contact hole 90. The third region 18A may be provided between the adjacent gate trenches 5 that are adjacent to each other in the X1-X2 direction. The third region 18A and the source region 13 may be alternately provided in the Y1-Y2 direction between two adjacent gate trenches 5 that are adjacent to each other in the X1-X2 direction. For example, the third region 18A may be provided near the end portion of the gate trench 5 in the Y1-Y2 direction, and the source region 13 may be provided near a central portion of the gate trench 5 in the Y1-Y2 direction. The third region 18A is provided on both sides of the gate trench 5 in the X1-X2 direction. The third region 18A and the source region 13 may be exposed via all of the contact holes 90. The third region 18A has a first side 18X extending in the Y1-Y2 direction.

The fourth region 18B is provided between the adjacent gate trenches 5 that are adjacent to each other in the Y1-Y2 direction. The fourth region 18B is covered with the interlayer insulating film 83 and the barrier metal film 84. The fourth region 18B is connected to the third region 18A in the X1-X2 direction. The third region 18A and the fourth region 18B are alternately provided in the X1-X2 direction. For example, a third dimension W3 of the third region 18A in the Y1-Y2 direction is larger than a fourth dimension W4 of the fourth region 18B in the Y1-Y2 direction.

The connection region 17 includes a p-type impurity, such as Al or the like, and has the p-type conductivity. The connection region 17 electrically connects the contact region 18 and the electric field mitigation region 16. The connection region 17 is provided between the adjacent gate trenches 5 that are adjacent to each other in the Y1-Y2 direction in the plan view viewed in the direction perpendicular to the first principal surface 1. The connection region 17 makes contact with the electric field mitigation region 16 on the virtual straight line L1. The connection region 17 makes contact with the body region 12 or the contact region 18. The connection region 17 may make contact with each of body region 12 and contact region 18. The connection region 17 is located between the electric field mitigation region 16 and the contact region 18. The connection region 17 is located closer to the second principal surface 2 than the contact region 18 is to the second principal surface 2. The connection region 17 is located closer to the first principal surface 1 than the electric field mitigation region 16 is to the first principal surface 1. For example, in the direction perpendicular to the second principal surface 2, the connection region 17 may be located between the fourth region 18B and the electric field mitigation region 16, and may make contact with each of the fourth region 18B and the electric field mitigation region 16. When the connection region 17 is located between the fourth region 18B and the electric field mitigation region 16 in the direction perpendicular to the second principal surface 2, and makes contact with each of the fourth region 18B and the electric field mitigation region 16, a series resistance between the fourth region 18B and the electric field mitigation region 16 can be reduced. An effective concentration of the p-type impurity in the connection region 17 may be approximately the same as the effective concentration of the p-type impurity in the electric field mitigation region 16. The effective concentration of the p-type impurity in the connection region 17 is 5×10¹⁷ cm⁻³ or higher and 5×10¹⁸ cm⁻³ or lower, for example.

As illustrated particularly in FIG. 4, the electric field mitigation region 16 mainly includes the first region 16A and the second region 16B, for example. The first region 16A has a first dimension W1 in the X1-X2 direction, and the second region 16B has a second dimension W2 in the X1-X2 direction. The second dimension W2 is smaller than the first dimension W1. The second region 16B is connected to the first region 16A in the Y1-Y2 direction. The first region 16A and the second region 16B are alternately provided in the Y1-Y2 direction. A center axis of the first region 16A extending in the Y1-Y2 direction and a center axis of the second region 16B extending in the Y1-Y2 direction are continuous. In the plan view viewed in the direction perpendicular to the first principal surface 1, first region 16A of the electric field mitigation region 16 and the third region 18A of the contact region 18 are arranged side by side in the X1-X2 direction. In the plan view viewed in the direction perpendicular to the first principal surface 1, a portion of the first region 16A and a portion of the third region 18A preferably overlap each other, and the entirety of first side 18X of the third region 18A more preferably overlaps a portion of the first region 16A.

If the plurality of gate trenches 5 arranged side by side in the Y1-Y2 direction is assumed to form one gate trench aggregate, the gate trench aggregate may be regarded as being divided into the plurality of gate trenches 5 by the fourth region 18B and the connection region 17.

The barrier metal film 84 covers an upper surface and a side surface of the interlayer insulating film 83, and a side surface of the gate insulating film 81. The barrier metal film 84 makes contact with each of the interlayer insulating film 83 and the gate insulating film 81. The barrier metal film 84 is formed of a material including titanium nitride (TiN), for example.

The source electrode 60 makes contact with the first principal surface 1. The source electrode 60 includes a contact electrode 61 and a source interconnect 62. The contact electrode 61 makes contact with the source region 13 and the third region 18A of the contact region 18 on the first principal surface 1. The contact electrode 61 is formed of a material including nickel silicide (NiSi), for example. The contact electrode 61 may be formed of a material including titanium (Ti), Al, and Si. The contact electrode 61 makes an ohmic contact with the source region 13 and the third region 18A of the contact region 18. The source interconnect 62 covers an upper surface and a side surface of the barrier metal film 84, and an upper surface of the contact electrode 61. The source interconnect 62 makes contact with each of the barrier metal film 84 and the contact electrode 61. The source interconnect 62 is formed of a material including Al, for example.

The passivation film 85 covers an upper surface of the source interconnect 62. The passivation film 85 makes contact with the source interconnect 62. The passivation film 85 is formed of a material including polyimide, for example.

The drain electrode 70 makes contact with the second principal surface 2. The drain electrode 70 makes contact with the silicon carbide single crystal substrate 50 on the second principal surface 2. The drain electrode 70 is electrically connected to the drift region 11. The drain electrode 70 is formed of a material including NiSi, for example. The drain electrode 70 may be formed of a material including Ti, Al, and Si. The drain electrode 70 makes an ohmic contact with the silicon carbide single crystal substrate 50.

In the direction perpendicular to the second principal surface 2, the upper end surface of the electric field mitigation region 16 may be spaced apart from bottom surface 4. In this case, the bottom surface 4 may be located in the drift region 11, and the side surface 3 may penetrate the source region 13 and the body region 12 and reach the drift region 11, for example. For example, the fifth region 11A may be provided between the upper end surface of the electric field mitigation region 16 and the bottom surface 4.

A buffer layer including an n-type impurity, such as nitride or the like, and having the n-type conductivity, may be provided between the silicon carbide single crystal substrate 50 and the seventh region 11C. An effective concentration of the n-type impurity in the buffer layer may be higher than the effective concentration of the n-type impurity in the seventh region 11C.

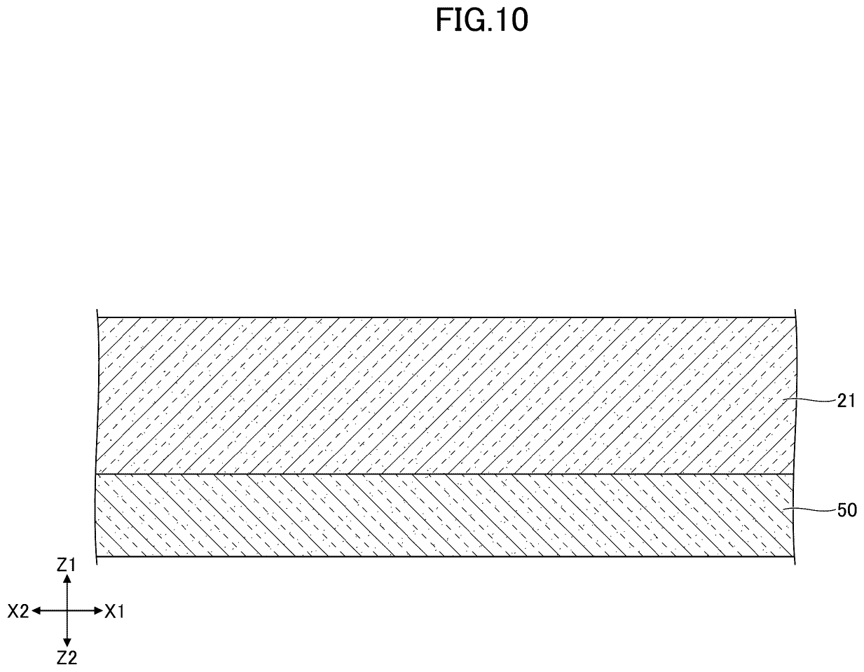

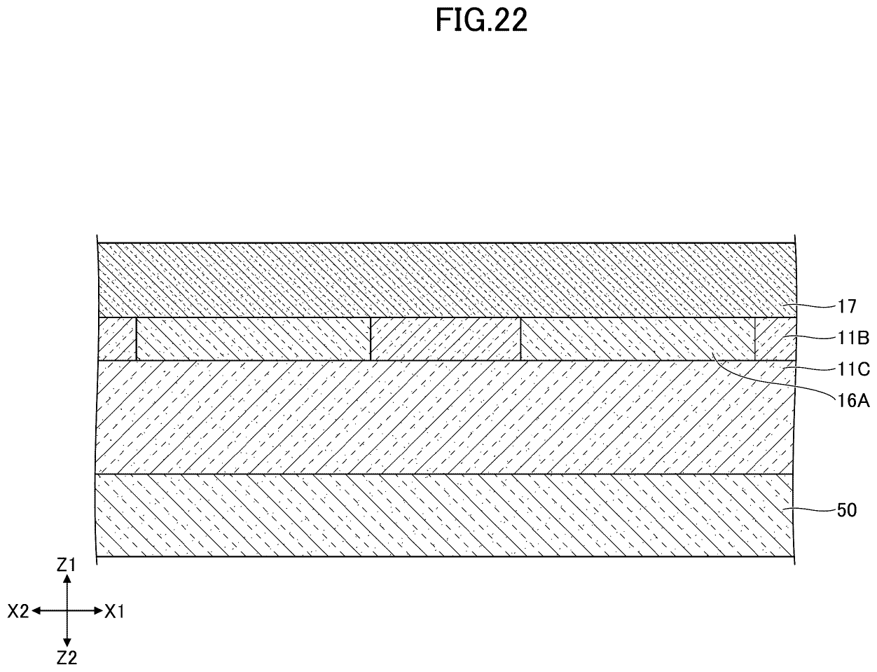

Next, a method for manufacturing the MOSFET 100 according to the embodiment will be described. FIG. 10 through FIG. 29 are cross sectional views illustrating the method for manufacturing the MOSFET 100 according to the embodiment. FIG. 10 through FIG. 21 illustrate changes from the cross section illustrated in FIG. 5. FIG. 22 through FIG. 29 illustrate changes from the cross section illustrated in FIG. 7.

First, as illustrated in FIG. 10, a process of preparing the silicon carbide single crystal substrate 50 is performed. For example, a silicon carbide ingot (not illustrated) manufactured by a sublimation method is sliced to prepare the silicon carbide single crystal substrate 50. A buffer layer (not illustrated) may be formed on the silicon carbide single crystal substrate 50. The buffer layer can be formed by chemical vapor deposition (CVD) using a gas mixture of silane (SiH₄) and propane (C₃H₈) as a source gas, for example, and using hydrogen (H₂) as a carrier gas, for example. During the epitaxial growth of the buffer layer, an n-type impurity, such as nitrogen or the like, for example, may be introduced into the buffer layer.

Next, as also illustrated in FIG. 10, a process of forming a first epitaxial layer 21 is performed. For example, the first epitaxial layer 21 is formed on the silicon carbide single crystal substrate 50 by CVD using a gas mixture of silane and propane as a source gas, for example, and using hydrogen as a carrier gas, for example. During the epitaxial growth, an n-type impurity, such as nitrogen or the like, for example, is introduced into the first epitaxial layer 21. The first epitaxial layer 21 has the n-type conductivity. An effective concentration of the n-type impurity in the first epitaxial layer 21 may be lower than the effective concentration of the n-type impurity in the buffer layer.

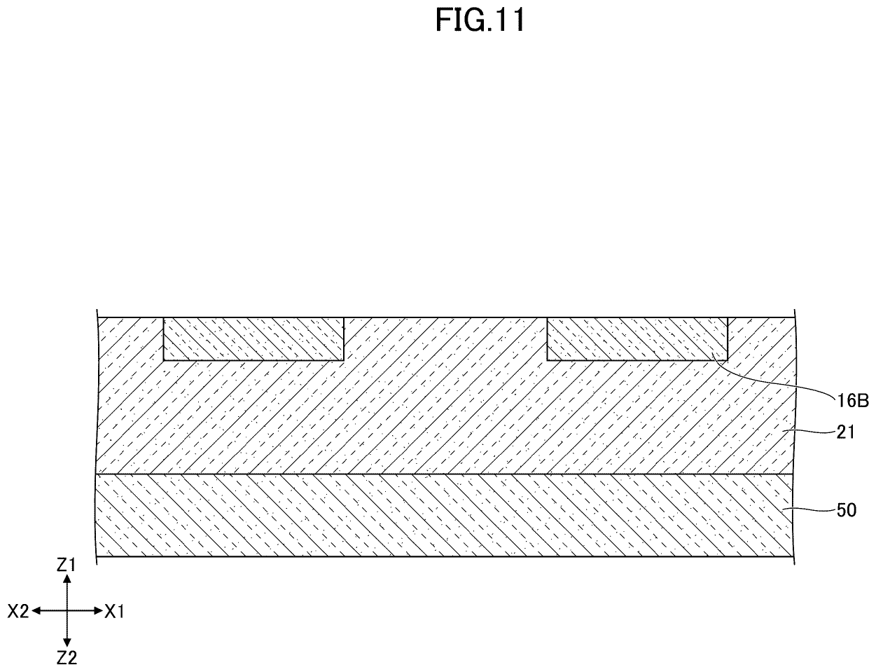

Next, as illustrated in FIG. 11, a process of forming the electric field mitigation region 16 is performed. For example, a mask layer (not illustrated), having an opening in a region where the electric field mitigation region 16 is to be formed, is formed. Next, p-type impurity ions capable of imparting p-type conductivity, such as aluminum ions or the like, for example, are implanted into the first epitaxial layer 21. Thus, the electric field mitigation region 16 is formed. Although only the second region 16B is illustrated in FIG. 11, the first region 16A is formed simultaneously with the second region 16B (refer to FIG. 22).

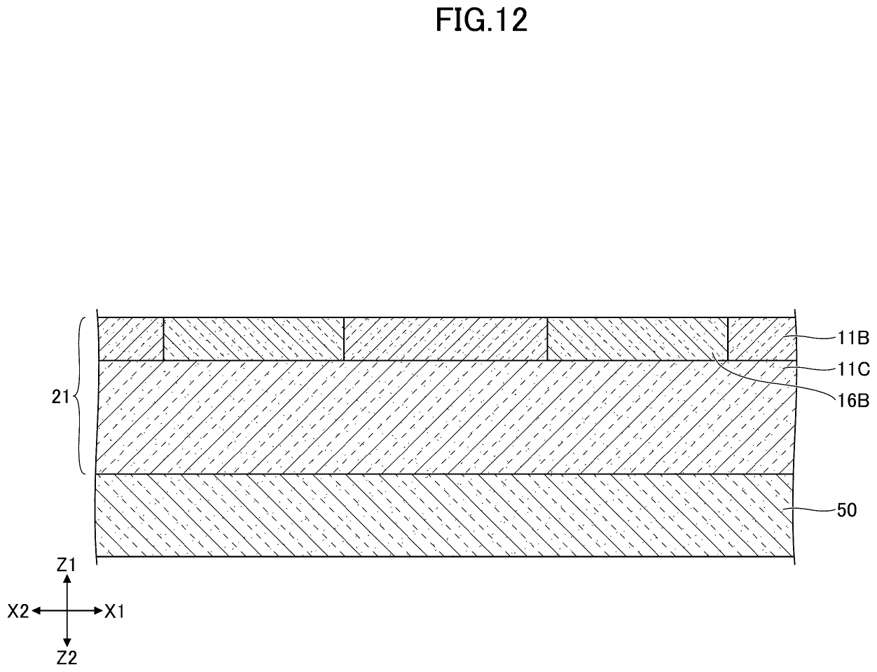

Next, as illustrated in FIG. 12, a process of forming the sixth region 11B is performed. For example, a mask layer (not illustrated), having an opening in a region where the sixth region 11B is to be formed, that is, in a region on a side of the electric field mitigation region 16 in the direction parallel to the second principal surface 2, is formed. Next, n-type impurity ions capable of imparting n-type conductivity, such as nitrogen or the like, are implanted into the first epitaxial layer 21. Hence, the sixth region 11B is formed. In the first epitaxial layer 21, a portion closer to the silicon carbide single crystal substrate 50 than the electric field mitigation region 16 is to the silicon carbide single crystal substrate 50, and a portion closer to the silicon carbide single crystal substrate 50 than the sixth region 11B is to the silicon carbide single crystal substrate 50, form the seventh region 11C. An effective concentration of the n-type impurity in the sixth region 11B is higher than the effective concentration of the n-type impurity in the seventh region 11C.

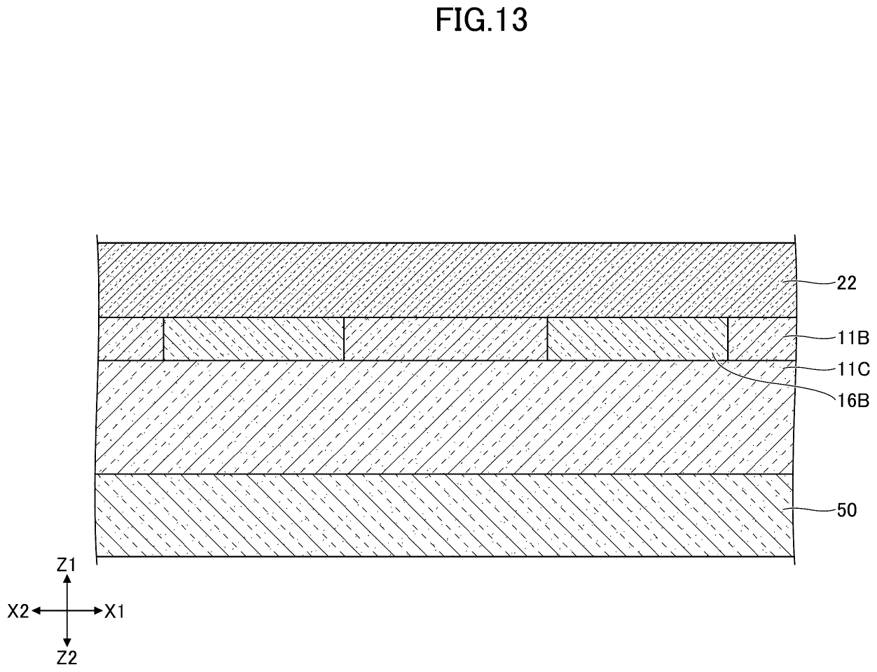

Next, as illustrated in FIG. 13, a process of forming the second epitaxial layer 22 is performed. The second epitaxial layer 22 is formed on the first epitaxial layer 21 by CVD using a gas mixture of silane and propane as a source gas, for example, and hydrogen as a carrier gas, for example. During the epitaxial growth, an n-type impurity, such as nitrogen or the like, is introduced into the second epitaxial layer 22. The second epitaxial layer 22 has the n-type conductivity. A thickness of the second epitaxial layer 22 is 0.8 μm or more and 1.2 μm or less, for example. For example, an effective concentration of the n-type impurity in the second epitaxial layer 22 is set lower than the effective concentration of the n-type impurity in the sixth region 11B.

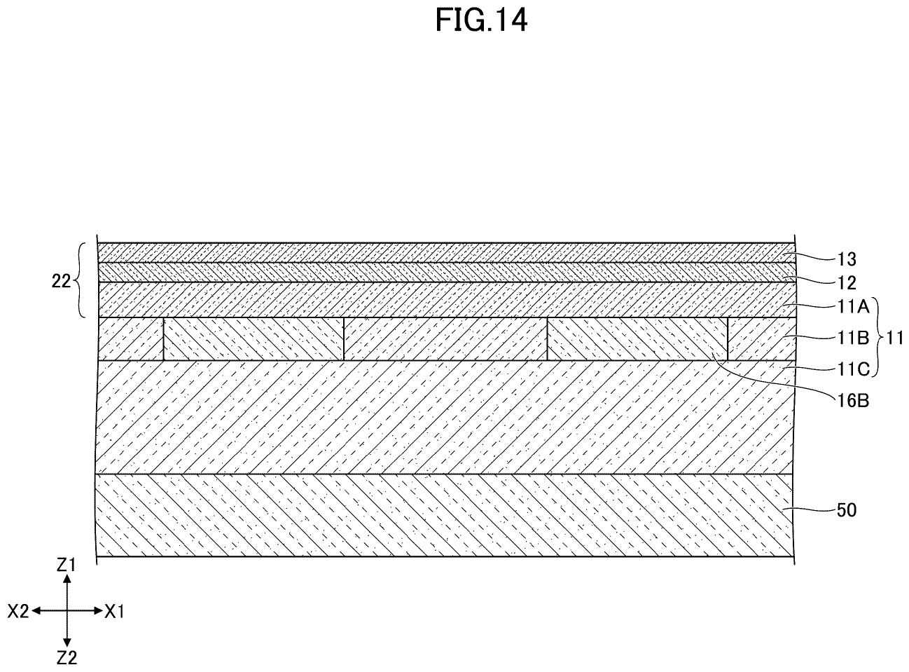

Next, as illustrated in FIG. 14, a process of forming the body region 12 is performed. For example, p-type impurity ions capable of imparting p-type conductivity, such as aluminum ions or the like, are implanted into the entire surface of the second epitaxial layer 22. Thus, the body region 12 is formed.

Next, as also illustrated in FIG. 14, a process of forming the source region 13 is performed. For example, n-type impurity ions capable of imparting n-type conductivity, such as phosphorus or the like, are implanted into the entire surface of the second epitaxial layer 22. Hence, the source region 13 is formed.

Next, as illustrated in FIG. 22, a process of forming the connection region 17 is performed. For example, a mask layer (not illustrated), having an opening in a region where the connection region 17 is to be formed, is formed. Next, p-type impurity ions capable of imparting p-type conductivity, such as aluminum ions or the like, are implanted into the source region 13, the body region 12, and the fifth region 11A. Thus, the connection region 17, making contact with the body region 12 and the electric field mitigation region 16, is formed.

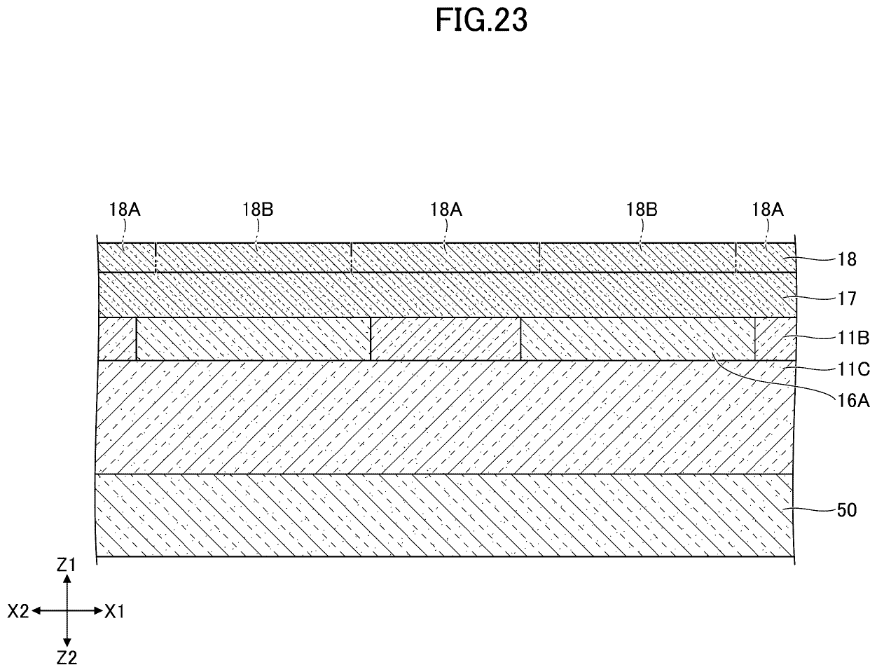

Next, as illustrated in FIG. 23, a process of forming the contact region 18 is performed. For example, a mask layer (not illustrated), having an opening in a region where the contact region 18 is to be formed, is formed. Next, p-type impurity ions capable of imparting p-type conductivity, such as aluminum ions or the like, are implanted into the connection region 17. Hence, the contact region 18, making contact with the body region 12 and the connection region 17, is formed.

Next, activation annealing is performed to activate the impurity ions implanted into the silicon carbide substrate 10. A temperature of the activation annealing is preferably 1500° C. or higher and 1900° C. or lower, and is approximately 1700° C., for example. An activation annealing time is approximately 30 minutes, for example. An activation annealing atmosphere is preferably an inert gas atmosphere, and is an Ar atmosphere, for example.

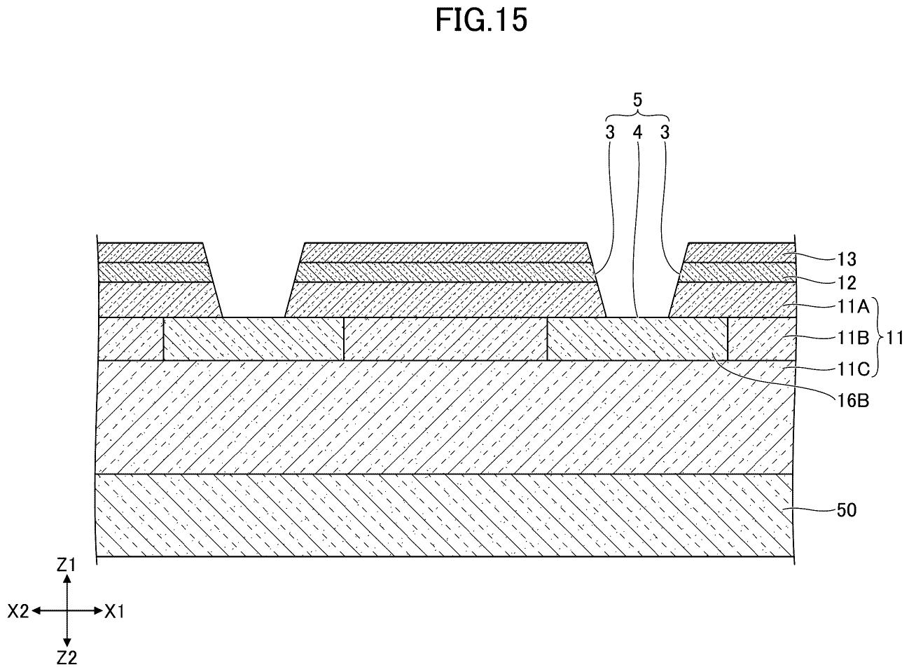

Next, as illustrated in FIG. 15, a process of forming the gate trench 5 is performed. For example, a mask layer (not illustrated), having an opening at a position where the gate trench 5 is to be formed, is formed on the first principal surface 1 including the source region 13 and the contact region 18. A portion of the source region 13, a portion of the body region 12, and a portion of the drift region 11 are removed by etching using the mask layer. Reactive ion etching, particularly inductively coupled plasma reactive ion etching, for example, can be used for the etching using the mask layer. In particular, inductively coupled plasma reactive ion etching using sulfur hexafluoride (SF₆) or a gas mixture of SEs and oxygen (O₂) as a reaction gas, for example, may be used for the reactive etching. By performing the etching, a recess (not illustrated) having a side portion substantially perpendicular to the first principal surface 1 and a bottom portion provided continuously with the side portion and substantially parallel to the first principal surface 1 is formed in a region where the gate trench 5 is to be formed.

Next, thermal etching is performed at the recess. The thermal etching can be performed by heating in an atmosphere including a reaction gas having at least one or more kinds of halogen atoms, for example, in a state where the mask layer is formed on the first principal surface 1. The at least one or more kinds of halogen atoms include at least one of chlorine (Cl) atoms and fluorine (F) atoms. The atmosphere includes chloride (Cl₂), boron trichloride (BCl₃), SFe, or tetrafluoromethane (CF₄), for example. For example, the thermal etching is performed using a gas mixture of chlorine gas and oxygen gas as the reaction gas, for example, and setting a heat treatment temperature to 800° C. or higher and 900° C. or lower, for example. The reaction gas may include a carrier gas in addition to the chlorine gas and the oxygen gas. For example, nitrogen gas, argon gas, helium gas, or the like may be used for the carrier gas.

By the thermal etching described above, the gate trench 5 is formed in the first principal surface 1 of the silicon carbide substrate 10. The gate trench 5 is defined by the side surface 3 and the bottom surface 4. The side surface 3 is formed by the source region 13, the body region 12, and the drift region 11. The bottom surface 4 is formed by the electric field mitigation region 16. The angle θ1 between the side surface 3 and the plane including the bottom surface 4 is 45° or more and 65° or less, for example. Next, the mask layer is removed from the first principal surface 1.

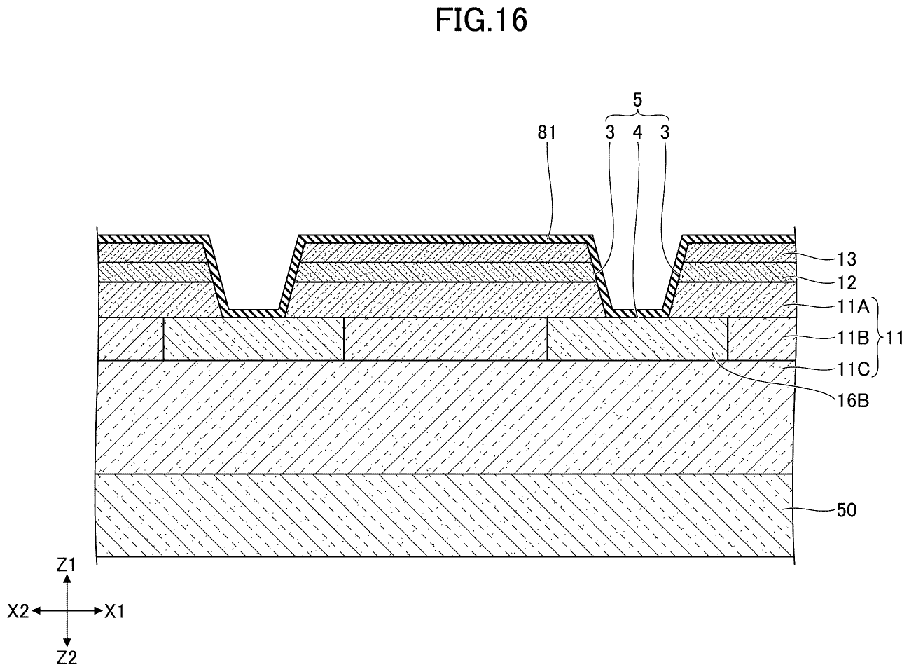

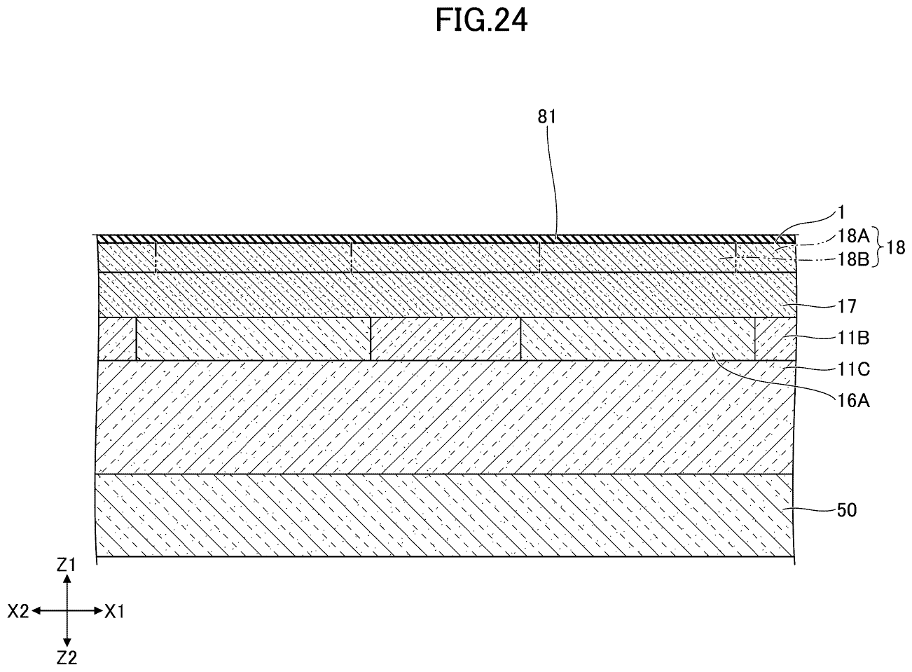

Next, as illustrated in FIG. 16 and FIG. 24, a process of forming the gate insulating film 81 is performed. For example, by thermally oxidizing the silicon carbide substrate 10, the gate insulating film 81 making contact with the source region 13, the body region 12, the drift region 11, the electric field mitigation region 16, and the contact region 18 is formed. Specifically, the silicon carbide substrate 10 is heated in an atmosphere including oxygen at a temperature of 1300° C. or higher and 1400° C. or lower, for example. Thus, the gate insulating film 81 making contact with the first principal surface 1, the side surface 3, and the bottom surface 4 is formed.

Next, a heat treatment (NO annealing) may be performed on the silicon carbide substrate 10 in a nitrogen monoxide (NO) gas atmosphere. In the NO annealing, the silicon carbide substrate 10 is held for approximately one hour under a condition in which the temperature is 1100° C. or higher and 1400° C. or lower, for example. Hence, nitrogen atoms are introduced into an interface region between the gate insulating film 81 and the body region 12. As a result, the formation of an interface state at the interface region is prevented, thereby improving a channel mobility.

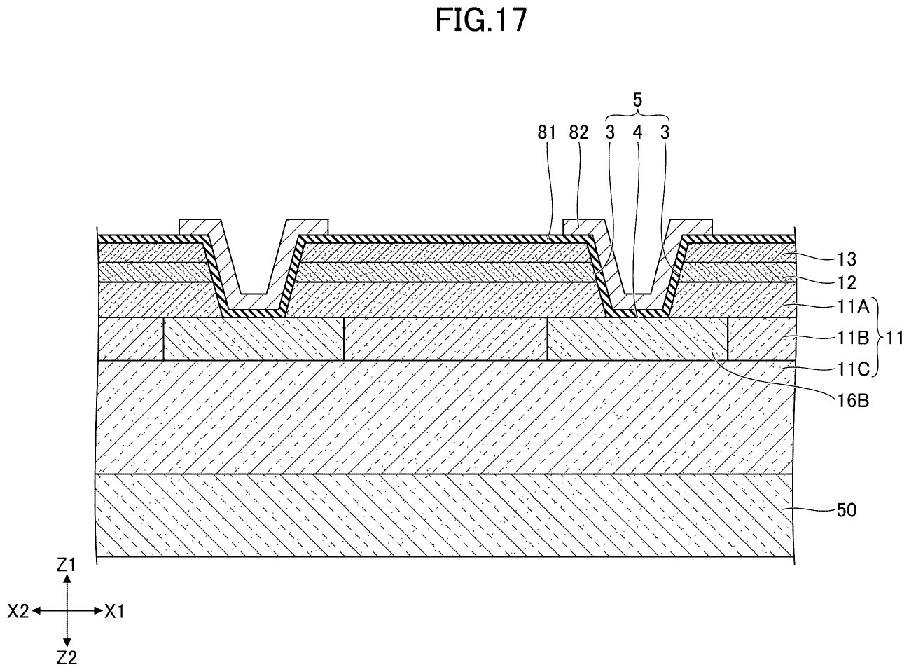

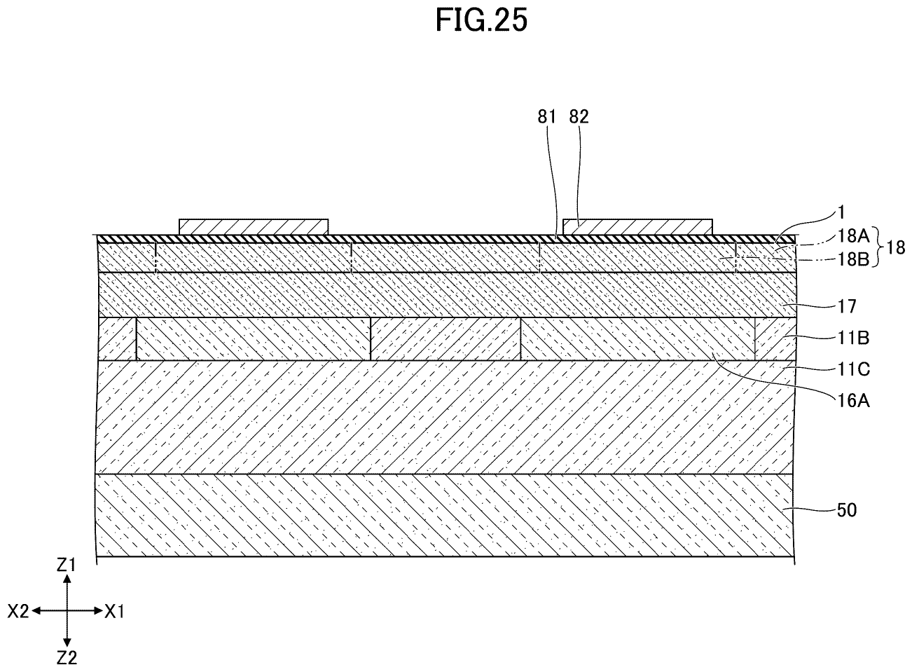

Next, as illustrated in FIG. 17 and FIG. 25, a process of forming the gate electrode 82 is performed. The gate electrode 82 is formed on the gate insulating film 81. The gate electrode 82 is formed by low pressure chemical vapor deposition (LP-CVD), for example. The gate electrode 82 is formed to oppose each of the source region 13, the body region 12, and the drift region 11.

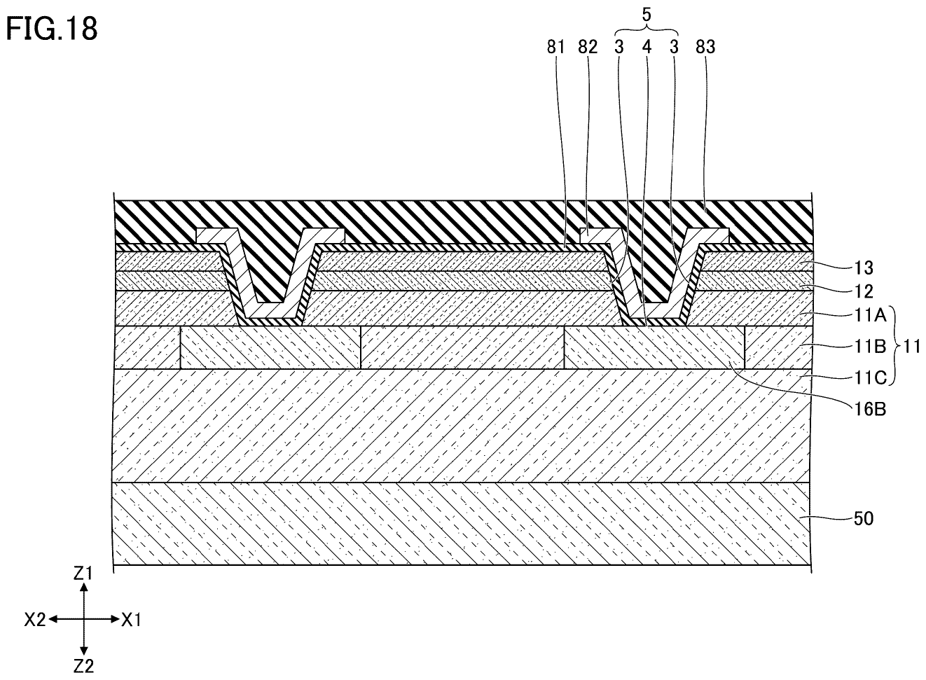

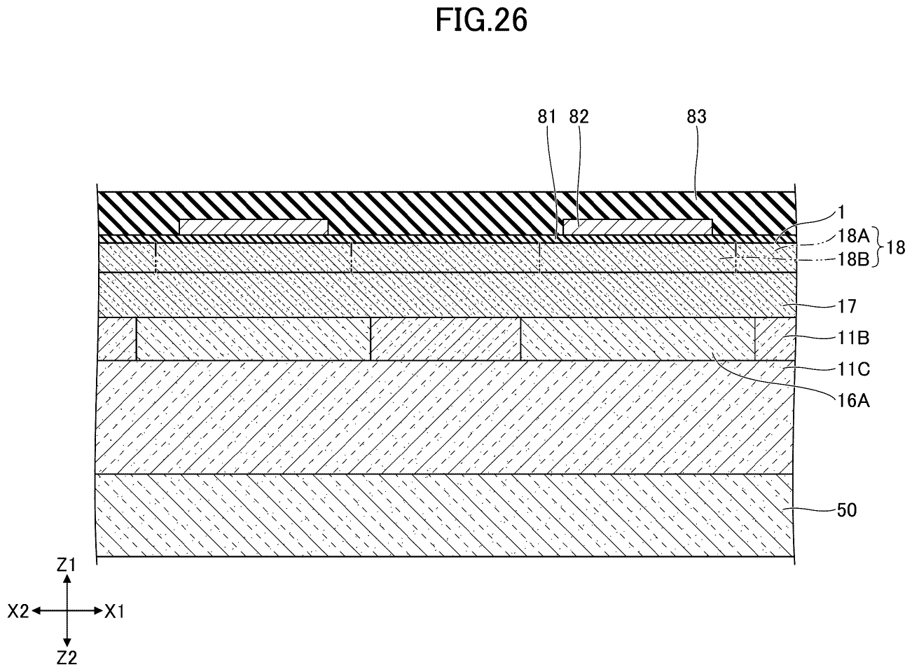

Next, as illustrated in FIG. 18 and FIG. 26, a process of forming the interlayer insulating film 83 is performed. Specifically, the interlayer insulating film 83 is formed to cover the gate electrode 82 and to make contact with the gate insulating film 81. The interlayer insulating film 83 is formed by CVD, for example. The interlayer insulating film 83 is formed of a material including silicon dioxide, for example. A portion of the interlayer insulating film 83 may be formed inside the gate trench 5.

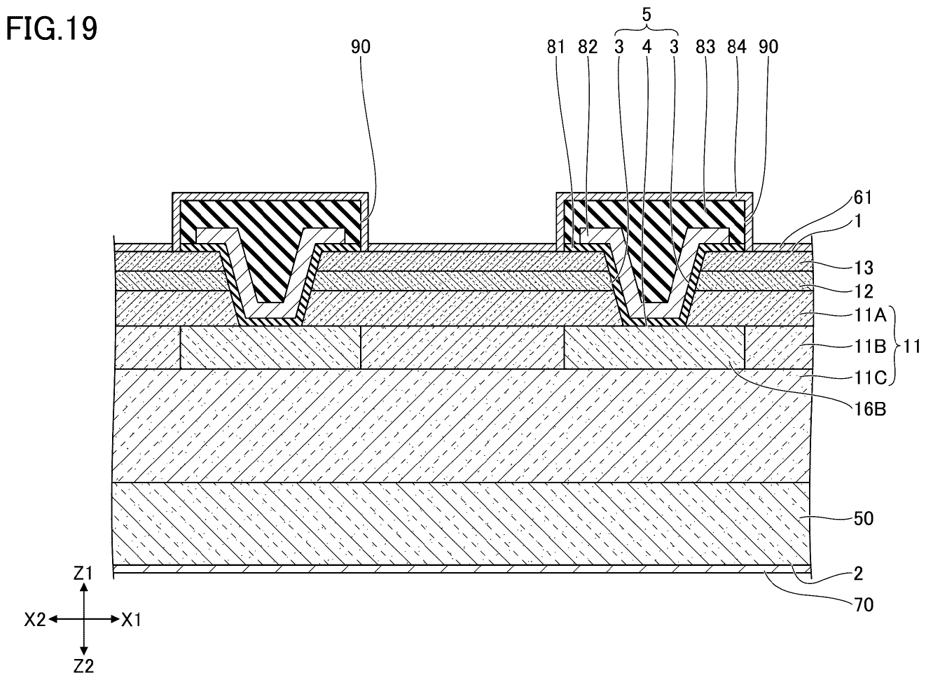

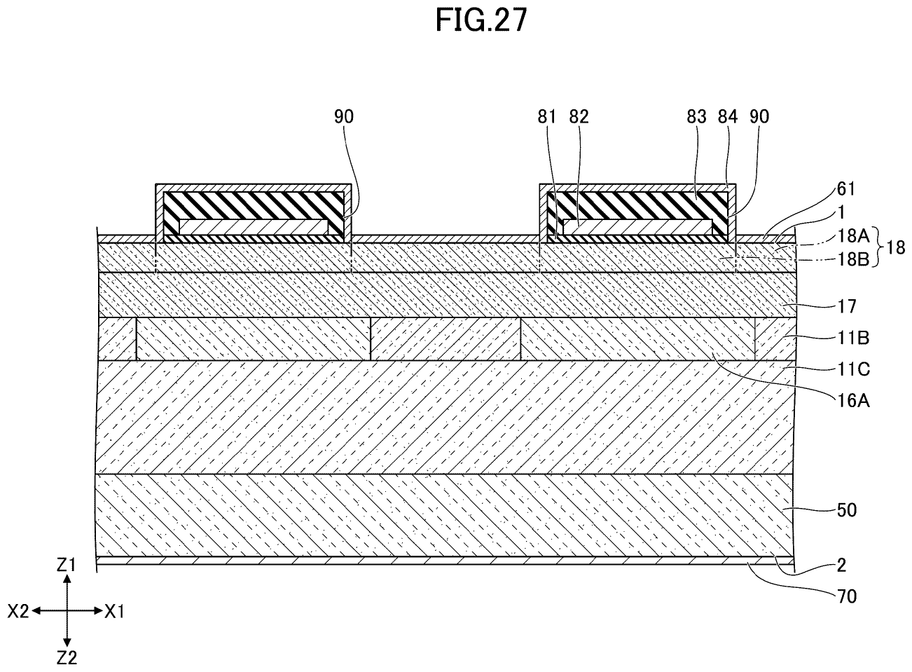

Next, as illustrated in FIG. 19 and FIG. 27, a process of forming the barrier metal film 84, the contact electrode 61, and the drain electrode 70 is performed. For example, etching is performed so that the contact hole 90 is formed in the interlayer insulating film 83 and the gate insulating film 81, and thus, the source region 13 and the third region 18A are exposed from the interlayer insulating film 83 and the gate insulating film 81 via the contact hole 90. Next, the barrier metal film 84 is formed to cover the upper surface and the side surface of the interlayer insulating film 83, and the side surface of the gate insulating film 81. The barrier metal film 84 is formed of a material including TiN, for example. The barrier metal film 84 is formed by film formation using sputtering and reactive ion etching (RIE), for example. Next, a metal film (not illustrated) for the contact electrode 61 is formed to make contact with the source region 13 and the third region 18A on the first principal surface 1. The metal film for the contact electrode 61 is formed by sputtering, for example. The metal film for the contact electrode 61 is formed of a material including Ni, for example. Next, a metal film (not illustrated) for the drain electrode 70 is formed to make contact with the silicon carbide single crystal substrate 50 on the second principal surface 2. The metal film for the drain electrode 70 is formed by sputtering, for example. The metal film for the drain electrode 70 is formed of a material including Ni, for example.

Next, alloying annealing is performed. The metal film for the contact electrode 61 and the metal film for the drain electrode 70 are held at a temperature of 900° C. or higher and 1100° C. or lower for approximately 5 minutes, for example. Thus, at least a portion of the metal film for the contact electrode 61 and at least a portion of the metal film for the drain electrode 70 react with the silicon included in the silicon carbide substrate 10 and are silicified. Thus, the contact electrode 61 in ohmic contact with the source region 13 and the third region 18A, and the drain electrode 70 in ohmic contact with the silicon carbide single crystal substrate 50, are formed. The contact electrode 61 may be formed of a material including Ti, Al, and Si. The drain electrode 70 may be formed of a material including Ti, Al, and Si.

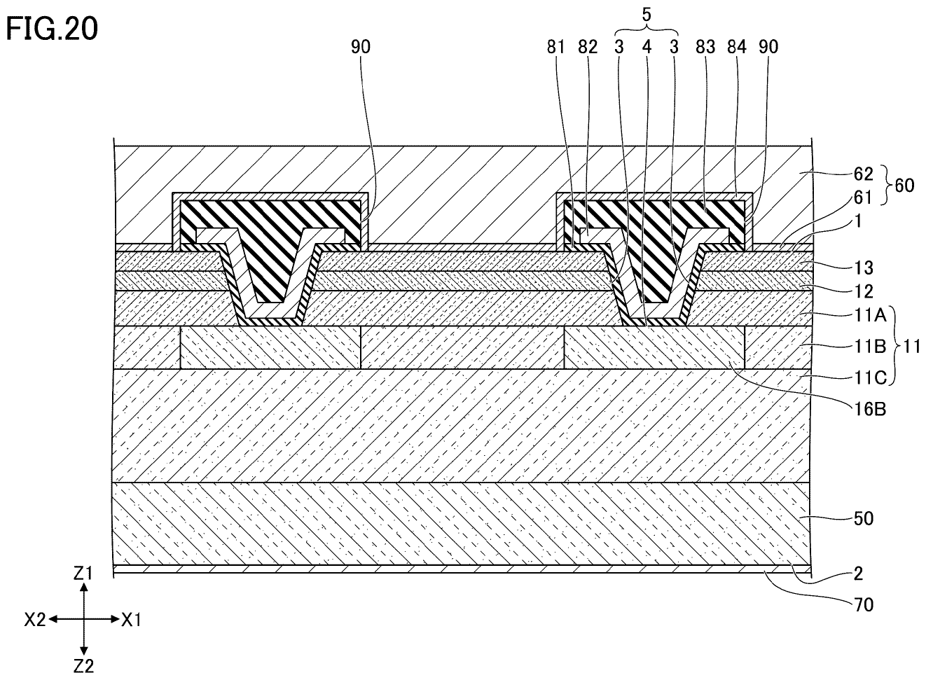

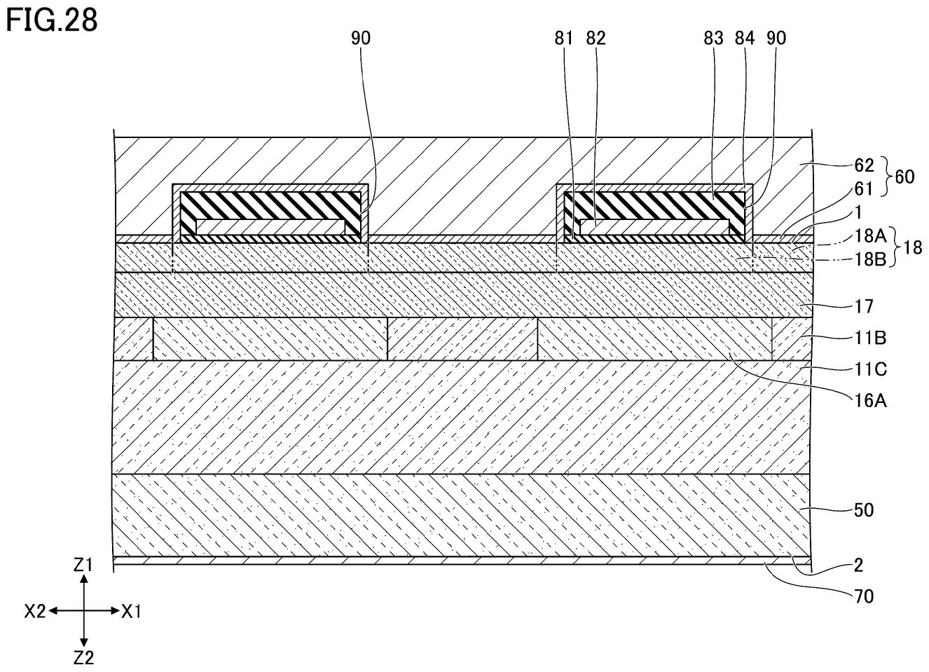

Next, as illustrated in FIG. 20 and FIG. 28, a process of forming the source interconnect 62 is performed. Specifically, the source interconnect 62 is formed to cover the contact electrode 61 and the barrier metal film 84. The source interconnect 62 is formed by film formation using sputtering and RIE, for example. The source interconnect 62 is formed of a material including aluminum, for example. Accordingly, the source electrode 60, including the contact electrode 61 and the source interconnect 62, is formed.

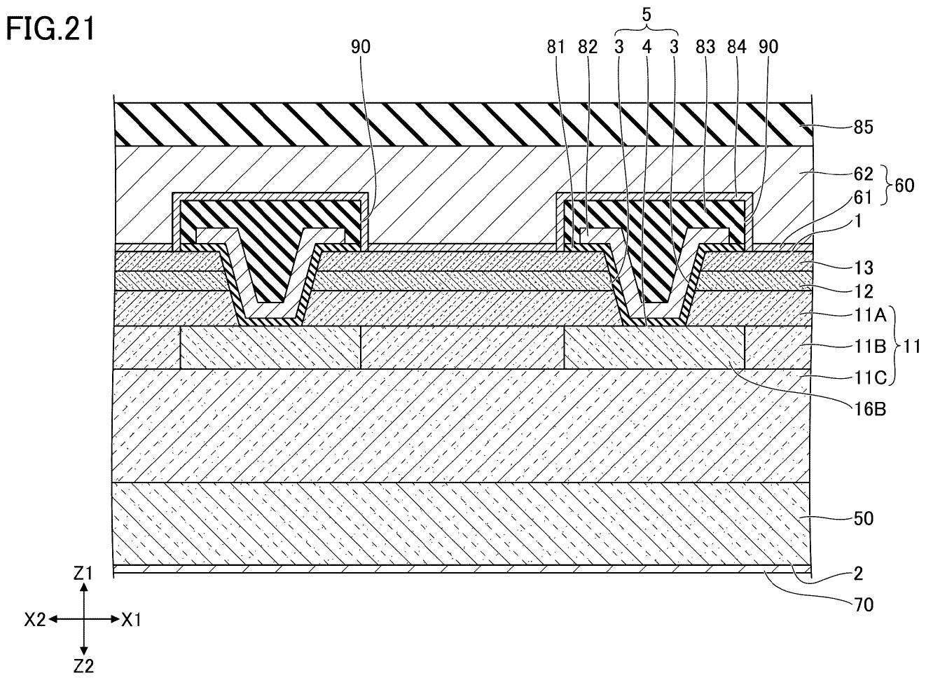

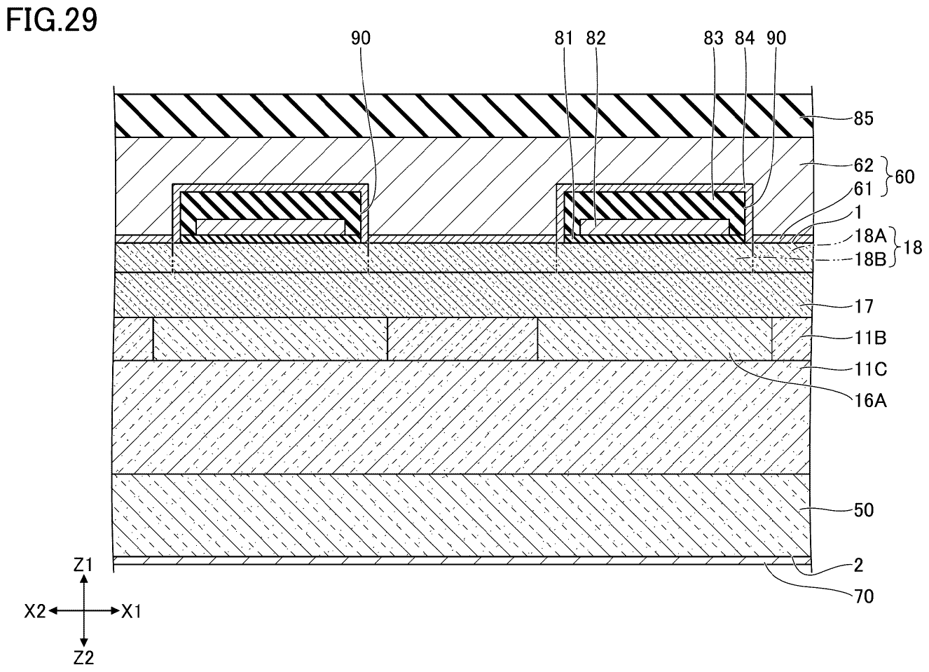

Next, as illustrated in FIG. 21 and FIG. 29, a process of forming the passivation film 85 is performed. Specifically, the passivation film 85 covering the source interconnect 62 is formed. The passivation film 85 is formed of a material including polyimide, for example. The passivation film 85 is formed by coating, for example. The passivation film 85 may be formed by plasma CVD.

In the manner described above, the MOSFET 100 according to the embodiment is completed.

Next, the operation and effects of the MOSFET according to the present embodiment will be described.

In the MOSFET 100 according to the present embodiment, the contact region 18 and the electric field mitigation region 16 are electrically connected via the connection region 17. The contact region 18 is electrically connected to the source electrode 60. Hence, the electric field mitigation region 16 is electrically connected to the source electrode 60. For this reason, carriers can be supplied from the source electrode 60 to the electric field mitigation region 16, and the feedback capacitance can be reduced. The switching loss is reduced by the reduction of the feedback capacitance, and it is possible to improve the switching speed.

In addition, the gate trench 5 and the electric field mitigation region 16 are located on the virtual straight line L1. That is, the gate trench 5 and the electric field mitigation region 16 overlap the virtual straight line L1. Further, the connection region 17 makes contact with the electric field mitigation region 16 on the virtual straight line L1. Accordingly, the connection region 17 is less likely to inhibit the drain current flowing along the portion of the side surface 3 parallel to the Y1-Y2 direction, that is, the portion of the side surface 3 spaced apart from the end portion of the gate trench 5 in the Y1-Y2 direction. For this reason, a sufficient drain current can be secured in the on state.

Moreover, the second dimension W2 of the second region 16B is smaller than the first dimension W1 of the first region 16A, and the first region 16A and the third region 18A are arranged side by side in the X1-X2 direction in the plan view viewed in the direction perpendicular to the first principal surface 1. For this reason, the concentration of the electric field in the contact region 18 on the side closer to the second principal surface 2 in the off state can be mitigated near the first region 16A, while securing the region in which the drain current flows in the on state near the second region 16B. Accordingly, the drain leakage caused by the concentration of the electric field can be reduced.

A portion of the first region 16A and a portion of the third region 18A preferably overlap each other in the plan view viewed in the direction perpendicular to the first principal surface 1. In this case, the concentration of the electric field at a position of the contact region 18 closer to the second principal surface 2 can easily be mitigated, and the drain leakage can easily be reduced. In addition, the entirety of the first side 18X of the third region 18A more preferably overlaps a portion of the first region 16A. In this case, the concentration of the electric field at a position of the contact region 18 closer to the second principal surface 2 can more easily be mitigated, and the drain leakage can more easily be reduced.

In the plan view viewed in the direction perpendicular to the first principal surface 1, the connection region 17 is provided between the adjacent gate trenches 5 that are adjacent to each other in the Y1-Y2 direction. Although the connection region 17 may be provided to overlap the gate trench 5 in the plan view viewed in the direction perpendicular to the first principal surface 1, a volume of the connection region 17 can be increased and the electrical resistance in connection region 17 can be reduced when the connection region 17 is provided between the adjacent gate trenches 5. Moreover, if the source region 13, the body region 12, and the drift region 11 are present between the end portion of the gate trench 5 in the Y1-Y2 direction and the fourth region 18B, the drain current can flow even in a region between the gate trench 5 and the fourth region 18B in the Y1-Y2 direction.

In the present embodiment, a semiconductor region provided near the upper end portion of the gate trench 5 is the n-type source region 13. The p-type contact region 18 may be present near the upper end portion of the gate trench 5, but the gate insulating film 81 tends to become thinner on the p-type contact region 18 than on the n-type source region 13. In addition, the electric field tends to easily concentrate near the upper end portion of the gate trench 5. But when the semiconductor region provided near the upper end portion of the gate trench 5 is the n-type source region 13, a thick gate insulating film 81 can more easily be formed, and a dielectric breakdown of the gate insulating film 81 caused by the concentration of the electric field near the upper end portion of the gate trench 5 can be prevented.

The third region 18A is provided on both sides of the gate trench 5 in the X1-X2 direction. For this reason, the electrical resistance between the source electrodes 60 and the electric field mitigation region 16 can be reduced compared to a case where the third region 18A is provided only on one side of the gate trench 5 in the X1-X2 direction.

In the direction perpendicular to the second principal surface 2, the connection region 17 is located between the fourth region 18B and the electric field mitigation region 16, and the connection region 17 makes contact with each of the fourth region 18B and the electric field mitigation region 16, so that the series resistance between the fourth region 18B and the electric field mitigation region 16 can be reduced.

A first effective concentration of the p-type impurity in the contact region 18 is preferably higher than a second effective concentration of the p-type impurity in the connection region 17. A contact resistance between the contact region 18 and the contact electrode 61 can be reduced by the high first effective concentration. If the second effective concentration is as high as the first effective concentration, the leakage current may easily flow due to introduction of crystal defects.

The third dimension W3 of the third region 18A in the Y1-Y2 direction may be larger than the fourth dimension W4 of the fourth region 18B in the Y1-Y2 direction. Because the contact electrode 61 makes ohmic contact with the third region 18A, the contact resistance between the third region 18A and the contact electrode 61 can be reduced as the third dimension W3 becomes larger. On the other hand, because the fourth region 18B is provided between the adjacent gate trenches 5 that are adjacent to each other in the Y1-Y2 direction, if the fourth dimension W4 is as large as the third dimension W3, the range in which the drain current flows is narrowed, and it may become difficult to obtain a sufficient drain current. By setting the third dimension W3 larger than the fourth dimension W4, it is possible to secure a wide range in which the drain current flows in the on state, while reducing the contact resistance between the third region 18A and the source electrode 60. Accordingly, the third dimension W3 is preferably larger than the fourth dimension W4.

For example, the third dimension W3 is preferably more than one times and six or less times the fourth dimension W4. If the third dimension W3 is larger than six times the fourth dimension W4, a region where the contact electrode 61 makes ohmic contact with the source regions 13 inside the contact hole 90 becomes small, and the contact resistance between the source region 13 and the contact electrode 61 may increase. But when the third dimension W3 is more than one times and six or less times the fourth dimension W4, it is possible to secure a wide range in which the drain current flows in the on state, while reducing the contact resistance between the third region 18A and the source electrode 60, and also reduce the contact resistance between the source region 13 and the source electrode 60. Accordingly, the third dimension W3 is more preferably two or more times and five or less times the fourth dimension W4.

For example, the third dimension W3 is preferably larger than a fifth dimension W5 of the source region 13 in the Y1-Y2 direction. In general, p-type impurities are less likely activated than n-type impurities. When the third dimension W3 set larger than the fifth dimension W5, it is possible to reduce each of the contact resistance between the third region 18A and the contact electrode 61 and the contact resistance between the source region 13 and the contact electrode 61.

For example, the third dimension W3 is preferably 0.2 or more times and 0.6 or less times a sum Wch of the third dimension W3 and the fifth dimension W5. When the third dimension W3 is less than 0.2 times the sum Wch, the contact resistance between the third region 18A and the contact electrode 61 may become too high. When the third dimension W3 is larger than 0.6 times the sum Wch, the contact resistance between the source region 13 and the contact electrode 61 may become too high. But when the third dimension W3 is 0.2 or more times and 0.6 or less times the sum Wch, each of the contact resistance between the third region 18A and the contact electrode 61 and the contact resistance between the source region 13 and the contact electrode 61 can be reduced. The third dimension W3 is more preferably 0.3 or more times and 0.6 or less times the sum Wch.

When the side surface 3 of the gate trench 5 includes the {0-33-8} plane, excellent mobility can be obtained in the channel, and the channel resistance can be reduced.

### [First Modification]

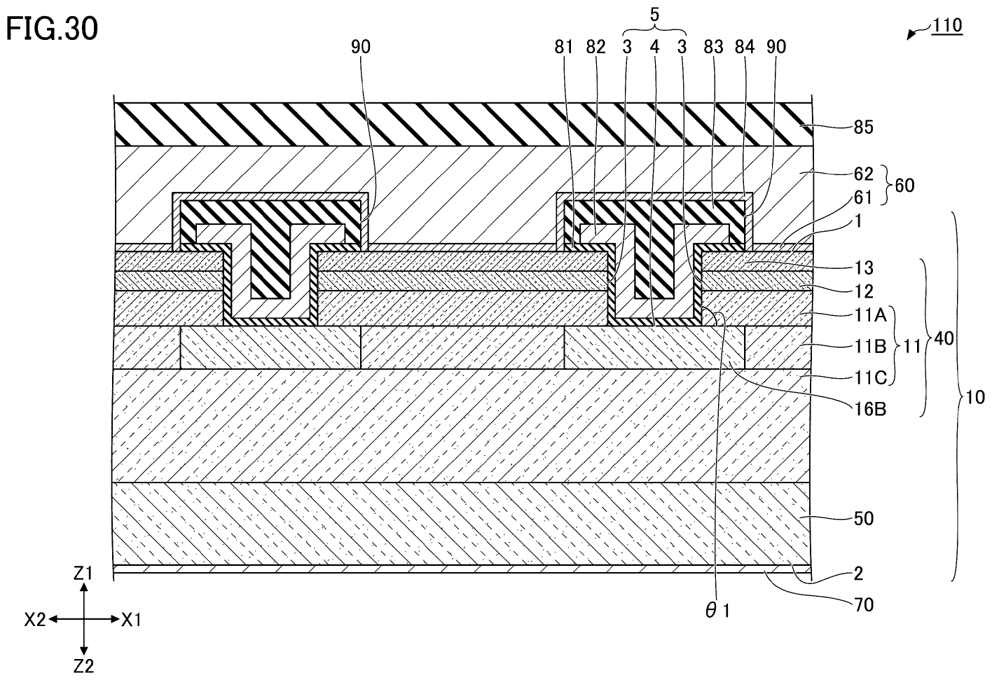

Next, a first modification of the embodiment will be described. The first modification differs from the embodiment mainly in the shape of the gate trench. FIG. 30 is a cross sectional view illustrating the configuration of the MOSFET (silicon carbide semiconductor device) according to the first modification of the embodiment. FIG. 30 illustrates a cross section similar to the cross section taken along the line V-V in FIG. 3.

As illustrated in FIG. 30, in a MOSFET 110 according to the first modification, the gate trench 5 is a vertical trench. That is, the angle θ1 of the side surface 3 with respect to the plane including the bottom surface 4 may be 90°. Otherwise, the configuration is the same as that of the embodiment.

The first modification can also obtain the same effects as those obtainable by the embodiment.

### [Second Modification]

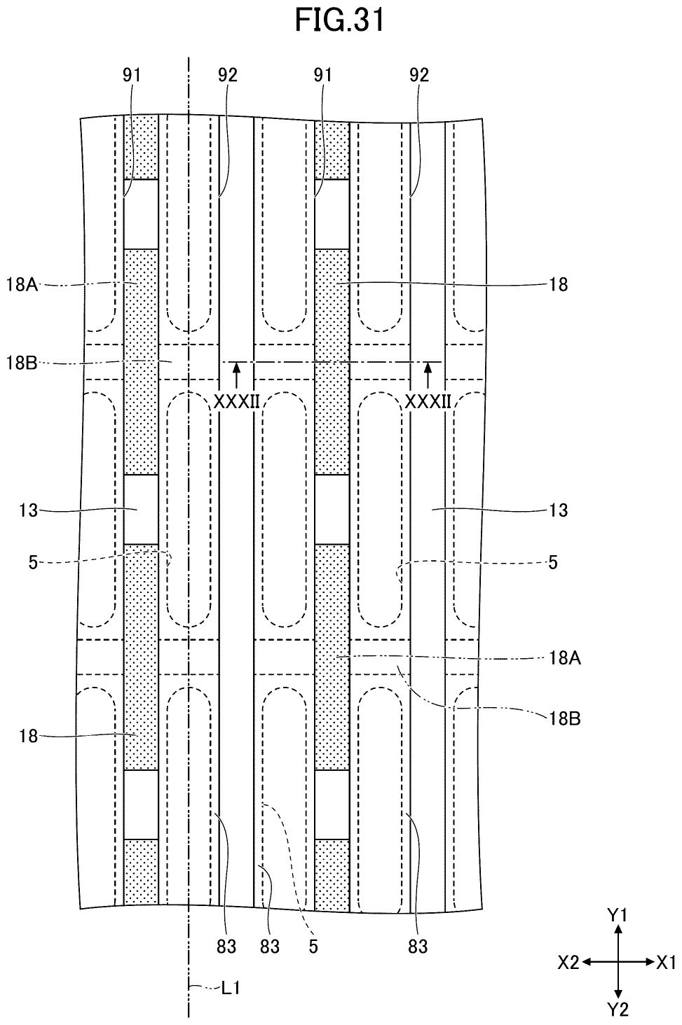

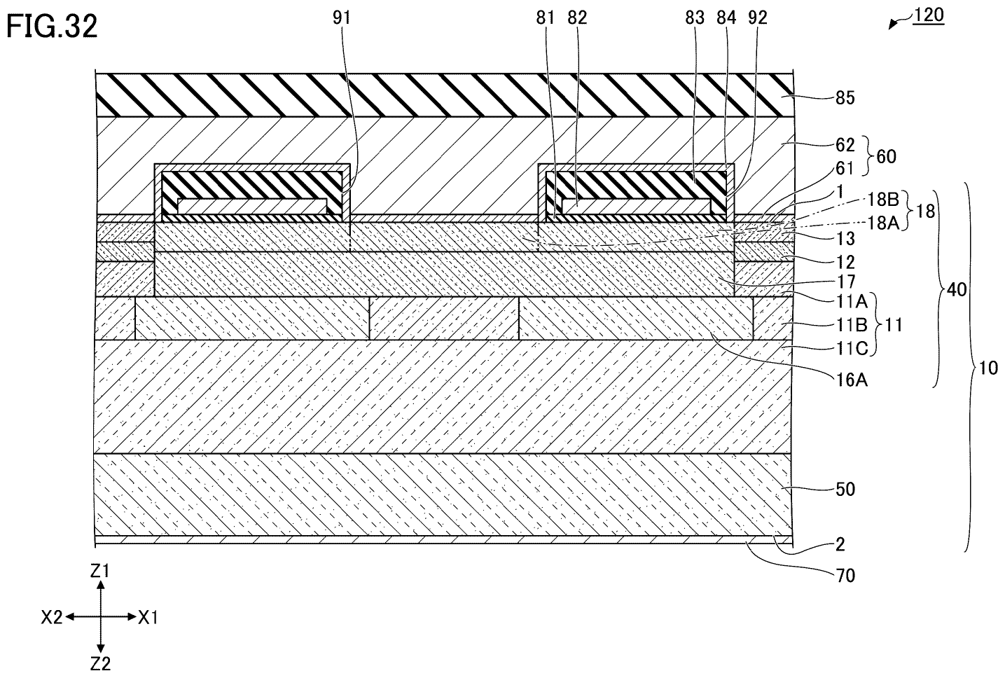

Next, a second modification of the embodiment will be described. The second modification example differs from the embodiment mainly in the position of the third region 18A. FIG. 31 is a diagram illustrating the configuration of the interlayer insulating film and the first principal surface in the silicon carbide semiconductor device according to the second modification of the embodiment. FIG. 32 is a cross sectional view illustrating the configuration of the silicon carbide semiconductor device according to the second modification of the embodiment. FIG. 32 corresponds to a cross sectional view taken along a line XXXII-XXXII in FIG. 31.

In a MOSFET 120 according to the second modification, as illustrated in FIG. 31 and FIG. 32, the third region 18A is provided only on one side of the gate trench 5 in the X1-X2 direction. A contact hole 91 and a contact hole 92 are formed in the interlayer insulating film 83. The contact hole 91 and the contact hole 92 are alternately arranged in the X1-X2 direction. The third region 18A may be provided in a portion of the first principal surface 1 exposed via the contact hole 91, and may not be provided in a portion of the first principal surface 1 exposed via the contact hole 92. The third region 18A and the source region 13 may be exposed via the contact hole 91. Only the source region 13 may be exposed via contact hole 92. Inside the contact hole 91, the contact electrode 61 makes ohmic contact with each of the source region 13 and the third region 18A. Inside the contact hole 92, the contact electrode 61 makes ohmic contact with the source region 13. Otherwise, the configuration is the same as that of the embodiment.

According to the second modification, the feedback capacitance can be reduced, the switching loss can be reduced by the reduction of the feedback capacitance, and the switching speed can be improved. The second modification can also secure a sufficient drain current. The second modification can also prevent the dielectric breakdown of the gate insulating film 81 due to the concentration of the electric field near the upper end portion of the gate trench 5. The second modification can also reduce the series resistance between the fourth region 18B and the electric field mitigation region 16.

### [Third Modification]

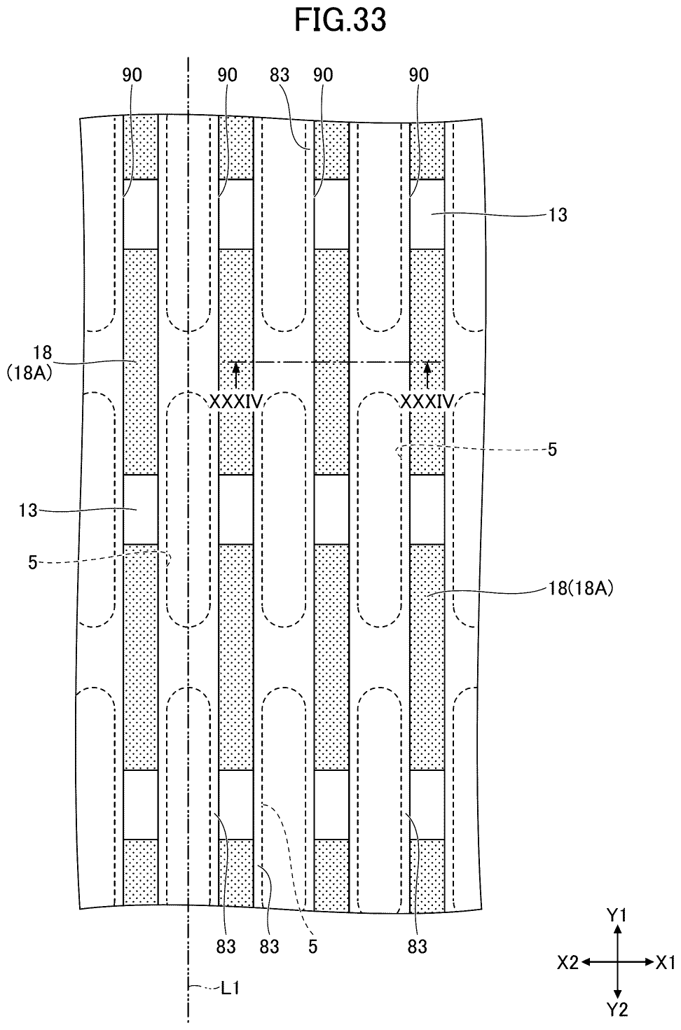

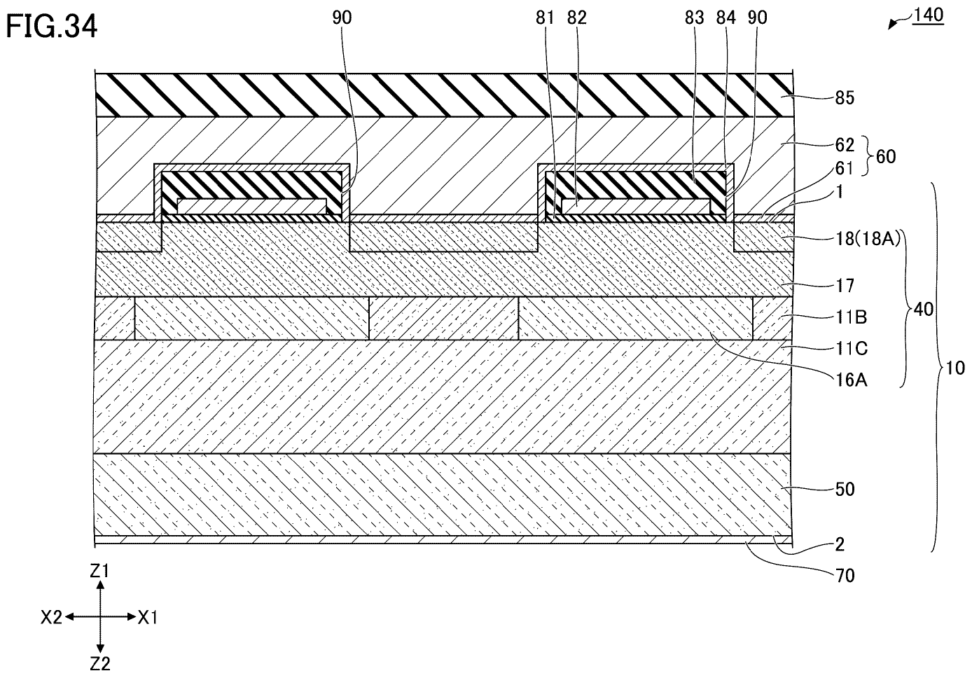

Next, a third modification of the embodiment will be described. The third modification differs from the embodiment mainly in the configuration of the contact region 18. FIG. 33 is a diagram illustrating the configuration of the interlayer insulating film and the first principal surface in the silicon carbide semiconductor device according to the third modification of the embodiment. FIG. 34 is a cross sectional view illustrating the configuration of the silicon carbide semiconductor device according to the third modification of the embodiment. FIG. 34 corresponds to a cross sectional view taken along a line XXXIV-XXXIV in FIG. 33.

In a MOSFET 140 according to the third modification, as illustrated in FIG. 33 and FIG. 34, the contact region 18 is formed by the third region 18A, and the contact region 18 does not include the fourth region 18B. The connection region 17 may form the first principal surface 1 below the interlayer insulating film 83 and the barrier metal film 84, between the adjacent gate trenches 5 that are adjacent to each other in the Y1-Y2 direction. The connection region 17 may make contact with the gate insulating film 81 and the barrier metal film 84. Otherwise, the configuration is the same as that of the embodiment.

According to the third modification, the feedback capacitance can be reduced, the switching loss can be reduced by the reduction of the feedback capacitance, and the switching speed can be improved. The third modification can also secure a sufficient drain current. The third modification can also prevent the dielectric breakdown of the gate insulating film 81 due to the concentration of the electric field near the upper end portion of the gate trench 5. The third modification can also reduce the electrical resistance between the source electrode 60 and the electric field mitigation region 16 compared to the case where the third region 18A is provided only on one side of the gate trench 5 in the X1-X2 direction.

### [Fourth Modification]

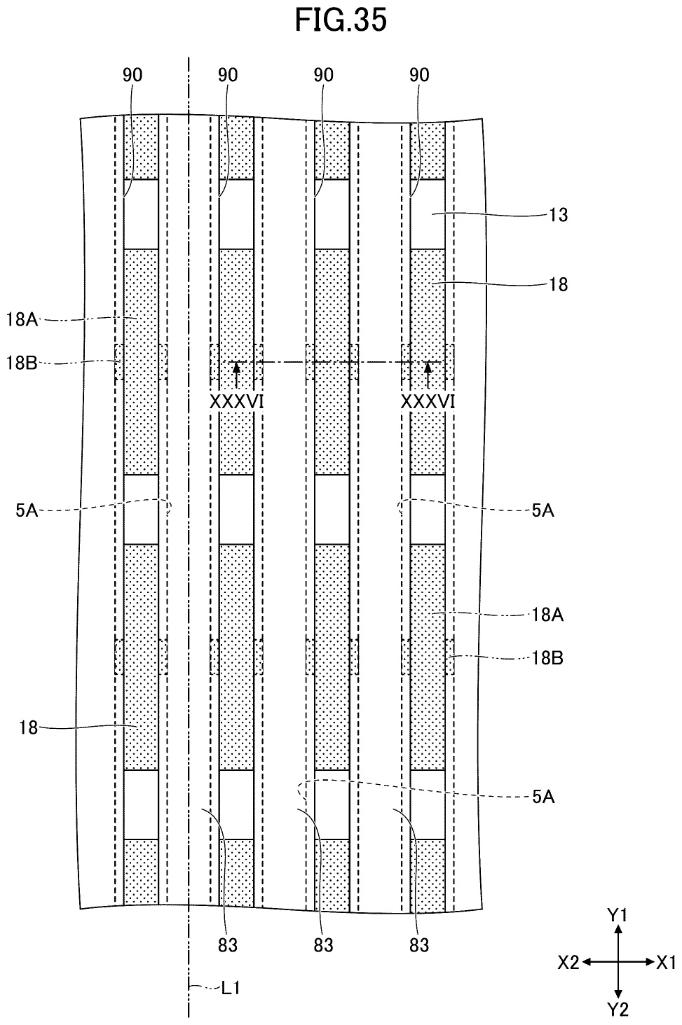

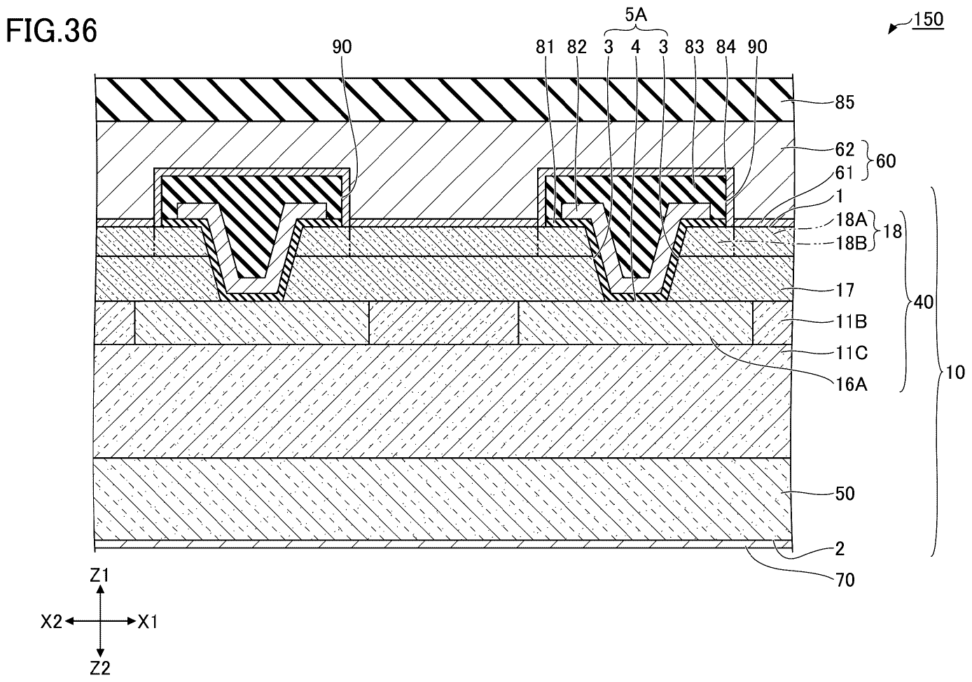

Next, a fourth modification of the embodiment will be described. The fourth modification differs from the embodiment mainly in the configuration of the gate trench 5. FIG. 35 is a diagram illustrating the configuration of the interlayer insulating film and the first principal surface in the silicon carbide semiconductor device according to the fourth modification of the embodiment. FIG. 36 is a cross sectional view illustrating the configuration of the silicon carbide semiconductor device according to the fourth modification of the embodiment. FIG. 36 is a cross sectional view taken along a line XXXVI-XXXVI in FIG. 35.

In a MOSFET 150 according to the fourth modification, as illustrated in FIG. 35 and FIG. 36, the plurality of gate trenches 5 arranged on the virtual straight line L1 in the embodiment are connected to each other to form a gate trench 5A. The fourth region 18B and the connection region 17 are provided on both sides of the gate trench 5A in the X1-X2 direction. The fourth region 18B and the connection region 17 may make contact with the side surface 3. Otherwise, the configuration is the same as that of the embodiment.

According to the fourth modification, the feedback capacitance can be reduced, the switching loss can be reduced by the reduction of the feedback capacitance, and the switching speed can be improved. According to the fourth modification, a sufficient drain current can be secured. The fourth modification can also reduce the electrical resistance between the source electrode 60 and the electric field mitigation region 16 when compared to the case where the third region 18A is provided only on one side of the gate trench 5 in the X1-X2 direction. The fourth modification can also reduce the series resistance between the fourth region 18B and the electric field mitigation region 16.

The contact hole may be formed to reach the fourth region, the fourth region may be exposed from the interlayer insulating film, and the source electrode may also be connected to the fourth region. In this case, the contact resistance between the contact region and the source electrode can further be reduced.

In the embodiments and the modifications described above, the n-type is described as the first conductivity type and the p-type is described as the second conductivity type, but the p-type may be the first conductivity type and the n-type may be the second conductivity type. In the embodiments and the modifications, the MOSFET is described as an example of the silicon carbide semiconductor device. However, the silicon carbide semiconductor device may be an insulated gate bipolar transistor (IGBT), for example. The effective concentration of the p-type impurity and the effective concentration of the n-type impurity in each of the impurity regions can be measured using a scanning capacitance microscope (SCM), a secondary ion mass spectrometry (SIMS), or the like, for example. The position of the boundary surface (that is, the pn junction interface) between the p-type region and the n-type region can be specified using the SCM, the SIMS, or the like, for example. A distribution of an effective concentration of majority carriers in a current diffusion region can be specified based on a distribution of a thickness of the depletion layer generated by the pn junction between the current diffusion region and the body region, for example, without measuring the effective concentration. The thickness of the depletion layer can be specified using the SCM, the SIMS, or the like, for example.

Although the embodiments are described above in detail, the present invention is not limited to the specific embodiments, and various variations and modifications can be made within the scope described in the claims.

### DESCRIPTION OF THE REFERENCE NUMERALS

1: First principal surface
2: Second principal surface
3: Side surface
4: Bottom surface
5, 5A: Gate trench
10: Silicon carbide substrate
11: Drift region
11A: Fifth region
11B: Sixth region
11C: Seventh region
12: Body region
13: Source region
16: Electric field mitigation region
16A: First region
16B: Second region
17: Connection region
18: Contact region
18A: Third region
18B: Fourth region
18X: First side
21: First epitaxial layer
22: Second epitaxial layer
40: Silicon carbide epitaxial layer
50: Silicon carbide single crystal substrate
60: Source electrode
61: Contact electrode
62: Source interconnect
70: Drain electrode
81: Gate insulating film
82: Gate electrode
83: Interlayer insulating film
84: Barrier metal film
85: Passivation film
90, 91, 92: Contact hole
100, 110, 120, 140, 150: Silicon carbide semiconductor
device (MOSFET)
W1: First dimension
W2: Second dimension
W3: Third dimension
W4: Fourth dimension
W5: Fifth dimension
Wch: Sum
θ1: angle

1. A silicon carbide semiconductor device comprising:
a silicon carbide substrate having a first principal surface and a second principal surface opposite to the first principal surface;
a source electrode;
a gate insulating film;
a gate electrode provided on the gate insulating film so that the gate insulating film is interposed between the silicon carbide substrate and the gate electrode; and
an interlayer insulating film covering the gate electrode, wherein:
the silicon carbide substrate includes:
a drift region having a first conductivity type;
a body region provided on the drift region and having a second conductivity type different from the first conductivity type;
a source region provided on the body region so as to be spaced apart from the drift region, and having the first conductivity type; and
a contact region provided on the body region and having the second conductivity type,
a gate trench is provided in the first principal surface, and is defined by a side surface penetrating the source region and the body region and reaching the drift region, and a bottom surface continuous with the side surface, the gate trench extending in a first direction parallel to the first principal surface,
the source electrode is connected to the source region and the contact region, the gate insulating film makes contact with the side surface and the bottom surface, the silicon carbide substrate includes:
an electric field mitigation region provided between the bottom surface and the second principal surface, extending in the first direction, and having the second conductivity type; and
a connection region electrically connecting the contact region and the electric field mitigation region, and having the second conductivity type,
the electric field mitigation region includes:
a first region having a first dimension in a second direction perpendicular to the first direction; and
a second region connected to the first region in the first direction and having a second dimension smaller than the first dimension in the second direction, a contact hole is formed in the interlayer insulating film, extends in the first direction, and exposes a portion of the source region,
the contact region includes a third region exposed via the contact hole and connected to the source electrode,
in a plan view viewed in a direction perpendicular to the first principal surface,
the gate trench and the electric field mitigation region overlap a virtual straight line extending in the first direction,
the connection region makes contact with the electric field mitigation region on the virtual straight line, and
the first region and the third region are arranged side by side in the second direction.

2. The silicon carbide semiconductor device as claimed in claim 1, wherein:
in the plan view viewed in the direction perpendicular to the first principal surface,
a portion of the first region and a portion of the third region overlap each other.

3. The silicon carbide semiconductor device as claimed in claim 2, wherein:
in the plan view viewed in the direction perpendicular to the first principal surface,
the third region has a first side extending in the first direction, and
an entirety of the first side overlaps a portion of the first region.

4. The silicon carbide semiconductor device as claimed in claim 1, wherein:
a plurality of the gate trenches are provided at constant intervals so as to overlap the virtual straight line, and
the connection region is provided between adjacent gate trenches that are adjacent to each other in the first direction in the plan view viewed in the direction perpendicular to the first principal surface.

5. The silicon carbide semiconductor device as claimed in claim 4, wherein:
in the plan view viewed in the direction perpendicular to the first principal surface,
the contact region further includes a fourth region provided between the adjacent gate trenches that are adjacent to each other in the first direction,
the third region has a third dimension in the first direction, and
the fourth region has a fourth dimension in the first direction smaller than the third dimension.

6. The silicon carbide semiconductor device as claimed in claim 5, wherein the third dimension is more than one times and six or less times the fourth dimension.

7. The silicon carbide semiconductor device as claimed in claim 5, wherein:
the source region and the third region are alternately provided in the first direction, and
the third dimension is larger than a fifth dimension of the source region in the first direction.

8. The silicon carbide semiconductor device as claimed in claim 5, wherein:
the source region and the third region are alternately provided in the first direction, and
the third dimension is 0.2 times or more and 0.6 times or less a sum of the third dimension and a fifth dimension of the source region in the first direction.

9. The silicon carbide semiconductor device as claimed in claim 5, wherein:
the fourth region is exposed from the interlayer insulating film, and
the source electrode is also connected to the fourth region.

10. The silicon carbide semiconductor device as claimed in claim 1, wherein the contact region includes the third region on both sides of the gate trench in the second direction.

11. The silicon carbide semiconductor device as claimed in claim 1, wherein the contact region includes the third region only on one side of the gate trench in the second direction.

12. The silicon carbide semiconductor device as claimed in claim 1, wherein a first effective concentration of an impurity of the second conductivity type in the contact region is higher than a second effective concentration of an impurity of the second conductivity type in the connection region.

13. The silicon carbide semiconductor device as claimed in claim 1, wherein the side surface of the gate trench includes a {0-33-8} plane.
